(19) United States
(12) Patent Application Publication
(10) Pub. No.: US 2022/0116557 A1
(43) Pub. Date: Apr. 14, 2022

(54) PIXEL ARRAY AND IMAGE SENSOR INCLUDING THE SAME

(71) Applicant: SAMSUNG ELECTRONICS CO., LTD., Suwon-si (KR)

(72) Inventors: Hongsuk LEE, Seoul (KR); Sanghyuck MOON, Hwaseong-si (KR); Jueun PARK, Seongnam-si (KR); Jungbin YUN, Hwaseong-si (KR)

(21) Appl. No.: 17/495,052

(22) Filed: Oct. 6, 2021

(30) Foreign Application Priority Data
Oct. 8, 2020 (KR) 10-2020-0130445
Jun. 24, 2021 (KR) 10-2021-0082330

(51) Int. Cl. H04N 5/355; H04N 5/378; H04N 5/3745; H01L 27/146

(52) U.S. Cl. CPC H04N 5/3559; H04N 5/378; H04N 5/37455; H01L 27/14636; H01L 27/14612; H01L 27/14643; H01L 27/14621

(57) ABSTRACT

A pixel array for an image sensor includes: a first pixel including a floating diffusion node, and a first selection transistor configured to output a first pixel signal generated using a voltage of the floating diffusion node of the first pixel; a second pixel including a floating diffusion node, and a second selection transistor configured to output a second pixel signal generated using a voltage of the floating diffusion node of the second pixel; and a column line connected to the first and second selection transistors. The floating diffusion nodes of the first and second pixels may be configured to be electrically connected to each other, and the first selection transistor and the second selection transistor may be configured to be turned on so that the first pixel signal and the second pixel signal are output to the column line, in a low conversion gain mode.

### CROSS-REFERENCE TO RELATED APPLICATIONS

This application is based on and claims priority under 35 U. S. C. § 119 to Korean Patent Application No. 10-2020-0130445, filed on Oct. 8, 2020, and Korean Patent Application No. 10-2021-0082330, filed on Jun. 24, 2021, in the Korean Intellectual Property Office, the disclosures of which are incorporated by reference herein in their entirety.

### BACKGROUND

### 1. Field

Embodiments relate to a pixel array and an image sensor including the same.

### 2. Description of the Related Art

The image sensor is an apparatus for capturing a two- or three-dimensional image of an object. The image sensor generates the image of the object by using a photoelectric conversion element reacting in accordance with the intensity of light reflected from the object. Recently, with the development of complementary metal-oxide semiconductor (CMOS) technology, a CMOS image sensor using the CMOS is being widely used.

### SUMMARY

According to an embodiment, there is provided a pixel array for an image sensor, the pixel array including: a first pixel including a floating diffusion node, and including a first selection transistor configured to output a first pixel signal generated using a voltage of the floating diffusion node of the first pixel; a second pixel including a floating diffusion node, and including a second selection transistor configured to output a second pixel signal generated using a voltage of the floating diffusion node of the second pixel; and a column line connected to both the first selection transistor and the second selection transistor. The floating diffusion node of the first pixel and the floating diffusion node of the second pixel may be configured to be electrically connected to each other, and the first selection transistor and the second selection transistor may be configured to be turned on so that the first pixel signal and the second pixel signal are output to the column line, in a low conversion gain mode.

According to an embodiment, there is provided a pixel array for an image sensor, the pixel array including: a plurality of column lines; and a plurality of pixels arranged in a matrix and including at least a first pixel and a second pixel that are connected to a first column line of the plurality of column lines, each of the first and second pixels including: a first floating diffusion node; a second floating diffusion node; a photoelectric conversion element configured to receive an optical signal and generate a corresponding charge; a transmission transistor configured to transmit the charge to the first floating diffusion node; a gain control transistor connected between the first floating diffusion node and the second floating diffusion node; a driving transistor configured to generate a pixel signal in accordance with a voltage of the first floating diffusion node; and a selection transistor configured to output the pixel signal to the first column line. The first and second floating diffusion nodes of the first and second pixels may be configured to be electrically connected to one another, and the selection transistors of the first and second pixels may be configured to be turned on, in a low conversion gain mode.

According to an embodiment, there is provided an image sensor, including: a pixel array including a plurality of pixels arranged in a matrix, in which a first pixel and a second pixel connected to a first column line are connected to each other; a row driver configured to drive the first pixel and the second pixel so that a floating diffusion node of the first pixel and a floating diffusion node of the second pixel are connected to each other in a low conversion gain mode, and the first pixel outputs a first pixel signal and the second pixel outputs a second pixel signal; and an analog-to-digital converter configured to analog-to-digital convert the first and second pixel signals output from the first column line.

### BRIEF DESCRIPTION OF THE DRAWINGS

Features will become apparent to those of skill in the art by describing in detail example embodiments with reference to the attached drawings in which:

FIG. 1 is a block diagram illustrating an image sensor according to an example embodiment;

FIG. 2 illustrates a pixel array according to an example embodiment;

FIGS. 3A and 3B illustrate an implementation of a pixel array according to an example embodiment;

FIGS. 4A and 4B are a view and a timing diagram illustrating a low conversion gain (LCG) mode operation of a pixel array according to an example embodiment;

FIG. 5 is a timing diagram of a pixel array according to an example embodiment;

FIGS. 6A and 6B are timing diagrams illustrating operations in accordance with shutter methods of a pixel array according to an example embodiment;

FIGS. 7A and 7B are vertical cross-sectional views in accordance with implementations of a pixel array according to an example embodiment;

FIG. 8 illustrates an implementation of a pixel array according to an example embodiment;

FIG. 9A illustrates an implementation of a pixel array according to an example embodiment and FIG. 9B is a timing diagram of the pixel array of FIG. 9A;

FIG. 10 illustrates a pixel array according to an example embodiment;

FIG. 11 illustrates an implementation of a pixel array according to an example embodiment;

FIG. 12 illustrates a pixel array according to an example embodiment;

FIG. 13 illustrates an implementation of a pixel array according to an example embodiment;

FIGS. 14A, 14B, and 14C illustrate color filters arranged in a pixel array according to an example embodiment;

FIG. 15 is a block diagram of an electronic device including a multi-camera module; and

FIG. 16 is a detailed block diagram of the camera module of FIG. 15.

### DETAILED DESCRIPTION

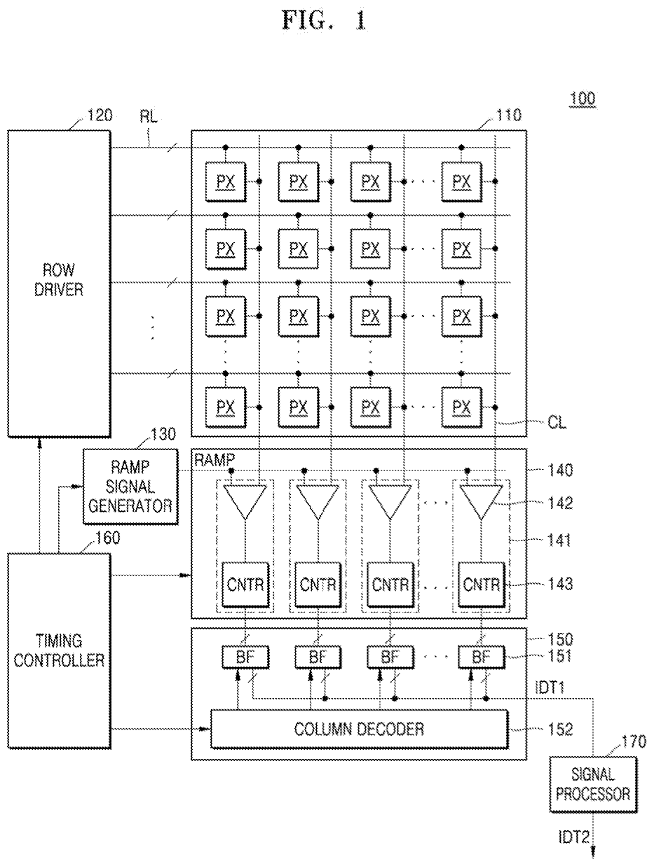

FIG. 1 is a block diagram illustrating an image sensor 100 according to an example embodiment.

The image sensor 100 may be mounted in an electronic device having an image sensing function or light sensing function. For example, the image sensor 100 may be mounted in an electronic device such as a camera, a smartphone, a wearable device, an Internet of Things (IoT) device, a tablet personal computer (PC), a personal digital assistant (PDA), a portable multimedia player (PMP), or a navigator. The image sensor 100 may be mounted in an electronic device provided as a part in a vehicle, furniture, manufacturing equipment, a door, or a measuring instrument.

The image sensor 100 may include a pixel array 110, a row driver 120, a ramp signal generator 130, an analog-to-digital converter (ADC) 140, a data output circuit 150, a timing controller 160, and a signal processor 170.

The pixel array 110 may include a plurality of row lines RL, a plurality of column lines CL, and a plurality of pixels PX connected to the plurality of row lines RL and the plurality of column lines CL and arranged in a matrix. The pixels PX arranged in the same column may be connected to the same column line CL.

A pixel PX may sense light by using a photoelectric conversion element, and may output an image signal that is an electrical signal in accordance with the sensed light. The photoelectric conversion element may be a light sensing element including an organic material or an inorganic material such as an inorganic photodiode, an organic photodiode, a perovskite photodiode, a phototransistor, a photo-gate, or a pinned photodiode.

In the pixel array 110 according to an example embodiment, at least two pixels PX connected to the same column line and adjacent to each other may share floating diffusion nodes respectively included in the at least two pixels PX. The pixel PX may have a dual conversion gain, and the at least two pixels PX may share the floating diffusion nodes through a gain control transistor for controlling a conversion gain in a low conversion gain mode. Selection transistors respectively included in the at least two pixels PX may be turned on. Thus, the plurality of selection transistors of the at least two pixels PX may be turned on. Therefore, at least two source followers included in the at least two pixels PX operate, and at least two pixel signals generated by the at least two source followers may be simultaneously provided to a column line CL. An average of the at least two pixel signals may be output to the ADC 140 through the column line CL. Therefore, noise in accordance with characteristic variation between transistors configuring a source follower of pixels PX may be reduced, and picture quality of an image generated by the image sensor 100 may improve.

In an example embodiment, the at least two pixels PX sharing the floating diffusion nodes may be arranged in different rows and the same column. In another example embodiment, the at least two pixels PX may be arranged in the same row and different columns.

In an example embodiment, on the at least two pixels PX, color filters of the same color or different colors may be arranged.

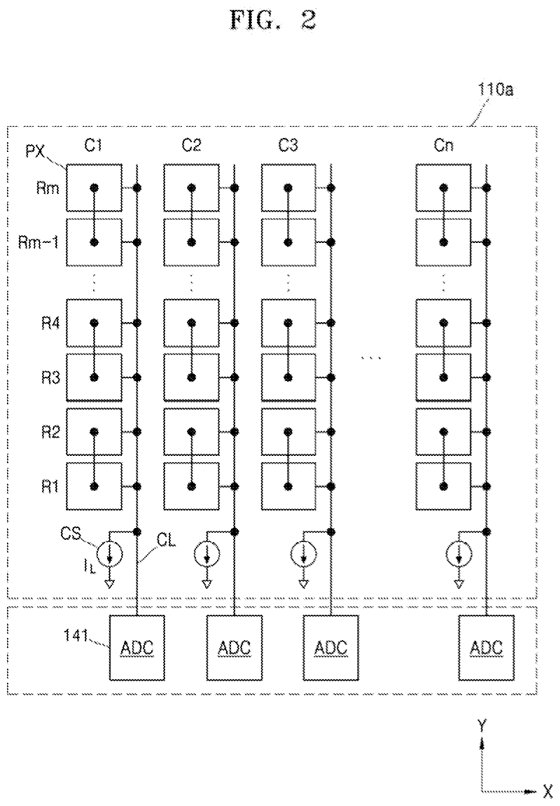

The pixel array 110 according to an example embodiment and the pixels PX included in the pixel array 110 will be described in detail with reference to FIGS. 2 to 14B.

The row driver 120 may drive the pixel array 110 in units of rows. The row driver 120 may decode a row control signal (e.g., an address signal) received from the timing controller 160, and may select at least one row line among row lines forming the pixel array 110 in response to the decoded row control signal. For example, the row driver 120 may generate a selection signal selecting one of a plurality of rows. The pixel array 110 may output a pixel signal (e.g., a pixel voltage) from a row selected by the selection signal provided by the row driver 120. The pixel signal may include a reset signal and the image signal.

The row driver 120 may transmit control signals for outputting the pixel signal to the pixel array 110, and the pixels PX may output the pixel signal by operating in response to the control signals.

The ramp signal generator 130 may generate a ramp signal (e.g., a ramp voltage) of which the level rises or falls with a predetermined slope in accordance with control of the timing controller 160. The ramp signal RAMP may be provided to each of a plurality of ADC circuits 141 included in the ADC 140.

The ADC 140 may include the plurality of ADC circuits 141, and each of the plurality of ADC circuits 141 may include a correlated double sampling (CDS) circuit 142 and a counter 143. The ADC 140 may convert the pixel signal (e.g., the pixel voltage) input from the pixel array 110 into a pixel value that is a digital signal. Each pixel signal received through each of the plurality of column lines CL may be converted into the pixel value that is a signal by a corresponding ADC circuit 141 among the plurality of ADC circuits 141.

The CDS circuit 142 may compare a pixel signal received through the column line CL, (e.g., a pixel voltage) with the ramp signal RAMP, and may output the comparison result as a comparison result signal. The CDS circuit 142 may output a comparison signal transited from a first level (e.g., a high level) to a second level (e.g., a low level) when a level of the ramp signal RAMP is the same as a level of the pixel signal. A point in time at which the level of the comparison signal is transited may be determined in accordance with the level of the pixel signal.

The CDS circuit 142 may sample the pixel signal provided by a pixel PX using a CDS method. The CDS circuit 142 may generate the comparison signal in accordance with the reset signal by sampling the reset signal received as the pixel signal and comparing the reset signal with the ramp signal RAMP. The CDS circuit 142 may store the reset signal. Then, the CDS circuit 142 may generate the comparison signal in accordance with the image signal by sampling the image signal correlated with the reset signal and comparing the image signal with the ramp signal RAMP.

The counter 143 may count the point in time at which the level of the comparison result signal output from the CDS circuit 142 is transited, and may output the counted value as the pixel value.

In an example embodiment, the counter 143 may be implemented by an up counter (in which the counted value sequentially increases based on a counting clock signal provided by the timing controller 160 and an operation circuit), an up/down counter, or a bit-wise inversion counter. In an example embodiment, the image sensor 100 may further include a code generator generating a plurality of code values having resolution in accordance with the set number of bits as a counting code, and the counter 143 may include a latch circuit latching a value of the counting code based on the comparison result signal and an operation circuit.

The data output circuit 150 may temporarily store and output the pixel value output from the ADC 140. The data output circuit 150 may include a plurality of column memories 151 and a column decoder 152. The plurality of column memories 151 may store the pixel value received from the counter 143. In an example embodiment, the plurality of column memories 151 may be respectively included in the plurality of counters 143. The plurality of pixel values stored in the plurality of column memories 151 may be output as image data IDT1 under control of the column decoder 152.

The timing controller 160 may control operations or timings of the row driver 120, the ramp signal generator 130, the ADC 140, and the data output circuit 150 by outputting the control signals to the row driver 120, the ramp signal generator 130, the ADC 140, and the data output circuit 150, respectively.

The signal processor 170 may perform image processing (e.g., noise reduction, gain correction, waveform shaping, interpolation, white balance processing, gamma processing, edge enhancement, and binning) on image data IDT1. In an example embodiment, the signal processor 170 may be included in a processor outside the image sensor 100.

Image-processed image data IDT2 may be provided to an external processor (e.g., a central processor unit (CPU), a graphics processing unit (GPU), or an application processor (AP)) of an electronic device including the image sensor 100.

FIG. 2 illustrates a pixel array 110a according to an example embodiment. The pixel array 110a of FIG. 2 may be applied to the image sensor 100 of FIG. 1 as the pixel array 110.

Referring to FIG. 2, the pixel array 110a may include a plurality of pixels PX arranged in a matrix. The plurality of pixels PX may be arranged in a plurality of rows and columns. For example, the plurality of pixels PX may be arranged in first to m^{th} rows R1 to Rm (m is a positive integer) and first to n^{th} columns C1 to Cn (n is a positive integer).

A plurality of row lines (RL of FIG. 1) may extend in a first direction, e.g., an X axis direction, and pixels arranged in the same row may be connected to the same row line. A plurality of column lines CL may extend in a second direction, e.g., a Y axis direction, and pixels arranged in the same column may be connected to the same column line.

A current source CS may be connected to each of the plurality of column lines CL. Based on a driving current IL provided by the current source CS, the pixel signal may be generated from at least one pixel selected from the pixels PX connected to the plurality of column lines CL, (e.g., at least one pixel PX in which a selection transistor is turned on) and may be provided to the ADC circuit 141 of the ADC 140.

The pixel array 110a may be driven in units of rows, and a plurality of pixel signals generated by the pixels PX arranged in the same row may be simultaneously provided to the ADC 140 through the plurality of column lines CL, and may be ADC converted.

In the pixel array 110a of FIG. 2, at least two adjacent pixels PX arranged in the same column may be electrically connected through an internal element. For example, referring to FIG. 2, two pixels PX respectively arranged in a first row R1 and a second row R2 may be connected to each other, two pixels PX respectively arranged in a third row R3 and a fourth row R4 may be connected to each other, and two pixels PX respectively arranged in an (m-1)^{th} row Rm-1 and an m^{th} row Rm may be connected to each other. Thus, pairs of pixels PX may be connected to together so as to share floating diffusion nodes.

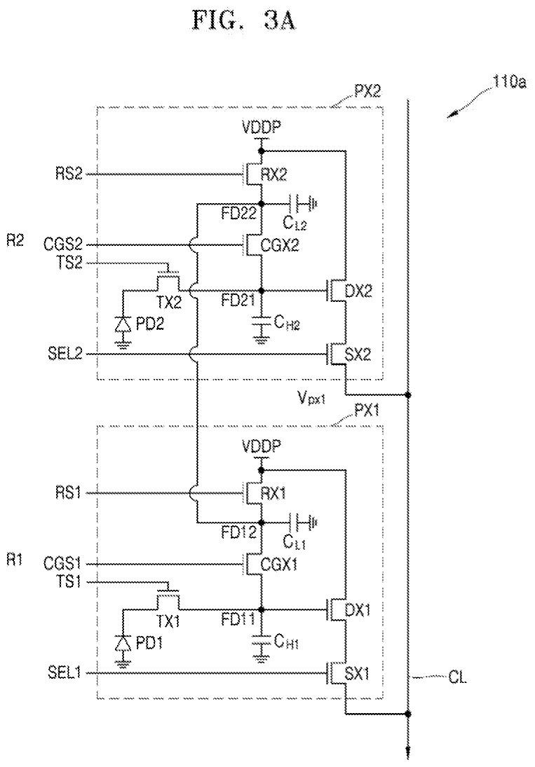

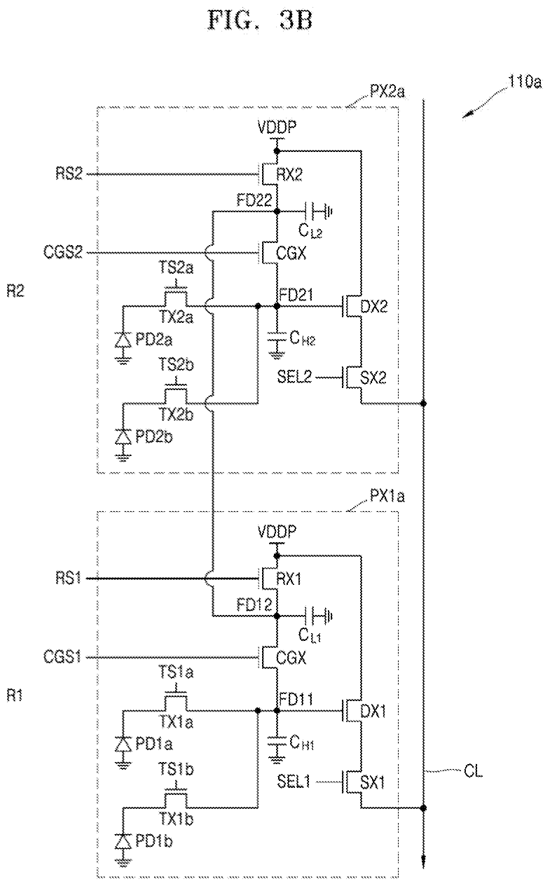

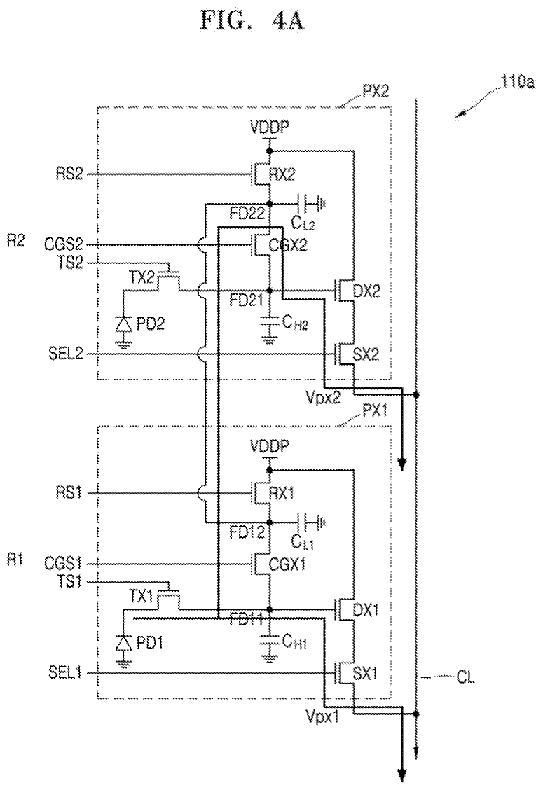

FIGS. 3A and 3B illustrate an implementation of a pixel array according to an example embodiment. FIGS. 3A and 3B illustrate an implementation of the pixel array 110a of FIG. 2. For convenience sake, two pixels PX1 and PX2 are illustrated.

Referring to FIG. 3A, the pixel array 110a may include the first pixel PX1 and the second pixel PX2 respectively arranged in the first row R1 and the second row R2. The first pixel PX1 and the second pixel PX2 may be connected to the same column line CL, and may also be internally connected to each other.

The first pixel PX1 may include a photoelectric conversion element PD1 and a plurality of transistors, e.g., a transmission transistor TX1, a reset transistor RX1, a gain control transistor CGX1, a driving transistor DX1, and a selection transistor SX1.

The photoelectric conversion element PD1 may convert light incident on the first pixel PX1 into an electrical signal. The photoelectric conversion element PD1 may be, e.g., a photodiode. The photoelectric conversion element PD1 may generate charges in accordance with light intensity. An amount of charges generated by the photoelectric conversion element PD1 may vary in accordance with a capturing environment (e.g., low light or high light) of an object. For example, in the high light environment, the amount of charges generated by the photoelectric conversion element PD1 may reach full well capacity (FWC) of the photoelectric conversion element PD1. However, in the low light environment, the amount of charges generated by the photoelectric conversion element PD1 may not reach the FWC of the photoelectric conversion element PD1.

The transmission transistor TX1, the reset transistor RX1, the driving transistor DX1, the selection transistor SX1, and the gain control transistor CGX1 may respectively operate in response to control signals provided by the row driver (120 of FIG. 1), e.g., a reset control signal RS1, a transmission control signal TS1, a selection signal SEL1, and a gain control signal CGS1.

The reset transistor RX1 may reset a first floating diffusion node FD11 and a second floating diffusion node FD12. The reset transistor RX1 may be turned on in response to the reset control signal RS1 applied to a gate terminal thereof, and may provide a pixel power voltage VDDP to the second floating diffusion node FD12 as a reset voltage. At this time, the gain control transistor CGX1 may be turned on together based on the gain control signal CGS1 received by the gate terminal thereof so that the pixel power voltage VDDP may be applied to the first floating diffusion node FD11. Therefore, the first floating diffusion node FD11 and the second floating diffusion node FD12 may be reset.

The transmission transistor TX1 may be turned on in response to the transmission control signal TS1, and may transmit the charges generated by the photoelectric conversion element PD1 to the first floating diffusion node FD11. The charges transmitted to the first floating diffusion node FD11 may be stored. Thus, a capacitor C_{H1} may be formed in the first floating diffusion node FD11, and the charges may be stored in the capacitor C_{H1} of the first floating diffusion node FD11. As the charges are stored in the capacitor C_{H1}, a voltage of the first floating diffusion node FD11 may be reduced. Therefore, in accordance with the amount of charges generated by the photoelectric conversion element PD1 and stored in the capacitor C_{H1}, the voltage of the first floating diffusion node FD11 may be determined. Thus, the charges accumulated in the first floating diffusion node FD11 may be converted into a voltage. A unit of the conversion gain may be, e.g., uV/e.

The conversion gain may be determined by capacitance of the first floating diffusion node FD11, and may be inversely proportional to a magnitude of the capacitance, e.g., the conversion gain may be reduced when the capacitance of the first floating diffusion node FD11 is increased, and may be increased when the capacitance of the first floating diffusion node FD11 is reduced.

The driving transistor DX1 may generate a pixel signal (e.g., a pixel voltage) based on the voltage of the first floating diffusion node FD11 applied to a gate thereof. The driving transistor DX1 may generate the pixel signal by amplifying the voltage of the first floating diffusion node FD11. The driving transistor DX1 may operate as a source follower.

The selection transistor SX1 may select a first pixel PX1. The selection transistor SX1 may be turned on in response to the selection signal SEL1 applied to the gate terminal thereof, and may output the pixel signal output from the driving transistor DX1 to a column line CL.

The gain control transistor CGX1 may be connected between the first floating diffusion node FD11 and the second floating diffusion node FD12. A capacitor C_{L1} may be formed at the second floating diffusion node FD12. The capacitor C_{L1} may be a passive element having fixed or variable capacitance, a parasitic capacitor formed by a source/drain of the gain control transistor CGX1, or a parasitic capacitor formed in another pixel, e.g., the second pixel PX2 that may be connected to the source/drain of the gain control transistor CGX1. The gain control transistor CGX1 may be turned on in response to the gain control signal CGS1, and may connect the second floating diffusion node FD12 to the first floating diffusion node FD11.

The second pixel PX2 may include a photoelectric conversion element PD2 and a plurality of transistors, e.g., a transmission transistor TX2, a reset transistor RX2, a gain control transistor CGX2, a driving transistor DX2, and a selection transistor SX2.

The transmission transistor TX2, the reset transistor RX2, the driving transistor DX2, the selection transistor SX2, and the gain control transistor CGX2 may respectively operate in response to control signals provided by the row driver (120 of FIG. 1), e.g., a reset control signal RS2, a transmission control signal TS2, a selection signal SEL2, and a gain control signal CGS2.

Operations of the transmission transistor TX2, the reset transistor RX2, the driving transistor DX2, the selection transistor SX2, and the gain control transistor CGX2 of the second pixel PX2 are the same as or similar to those of the transmission transistor TX1, the reset transistor RX1, the driving transistor DX1, the selection transistor SX1, and the gain control transistor CGX1 of the first pixel PX1.

Referring to FIG. 3A, a second floating diffusion node FD22 of the second pixel PX2 may be connected to the second floating diffusion node FD12 of the first pixel PX1. Therefore, when the gain control transistor CGX1 of the first pixel PX1 and the gain control transistor CGX2 of the second pixel PX2 are turned on, the first floating diffusion node FD11 and the second floating diffusion node FD12 of the first pixel PX1 and the first floating diffusion node FD21 and the second floating diffusion node FD22 of the second pixel PX2 may be electrically connected. Because the capacitance of the first floating diffusion node FD11 of the first pixel PX1 and the first floating diffusion node FD21 of the second pixel PX2 increases, a conversion gain may decrease. The gain control transistor CGX1 of the first pixel PX1 and the gain control transistor CGX2 of the second pixel PX2 may be turned off in a high conversion gain (HCG) mode, and may be turned on in a low conversion gain (LCG) mode.

As described above, the first pixel PX1 and the second pixel PX2 may operate in one of the HCG mode and the LCG mode in accordance with turn-on or turn-off of gain control transistors CGX1 and CGX2. In the HCG mode, because conversion gains of the pixels (e.g., a conversion gain of the first pixel PX1) may increase, gains of circuits (e.g., the ADC 140) for processing the pixel signal output from the first pixel PX1 may be able to be reduced. Therefore, a signal to noise ratio (SNR) of the image sensor (100 of FIG. 1) may be increased, and thus a minimum detectable amount of light may be reduced and low light intensity detection performance of the image sensor 100 may be improved. In the LCG mode, because the capacitance of the first floating diffusion node FD11 increases, FWC may increase. Therefore, the high light intensity detection performance of the image sensor 100 may improve.

Referring to FIG. 3B, a first pixel PX1a may include a plurality of photoelectric conversion elements, e.g., first and second photoelectric conversion elements PD1a and PD1b, and a plurality of transmission transistors respectively connected to the plurality of photoelectric conversion elements, e.g., first and second transmission transistors TX1a and TX1b. The first and second transmission transistors TX1a and TX1b may be turned on or turned off in response to first and second transmission control signals TS1a and TS1b. The first and second transmission control signals TS1a and TS1b may be the same or different from each other.

A second pixel PX2a may include first and second photoelectric conversion elements PD2a and PD2b and first and second transmission transistors TX2a and TX2b. The first and second transmission transistors TX2a and TX2b may be turned on or turned off in response to first and second transmission control signals TS2a and TS2b.

In FIG. 3B, it is illustrated that each of the first pixel PX1a and the second pixel PX2a includes two photoelectric conversion elements and two transmission transistors. However, each of the first pixel PX1a and the second pixel PX2a may include, e.g., three or more photoelectric conversion elements and three or more transmission transistors.

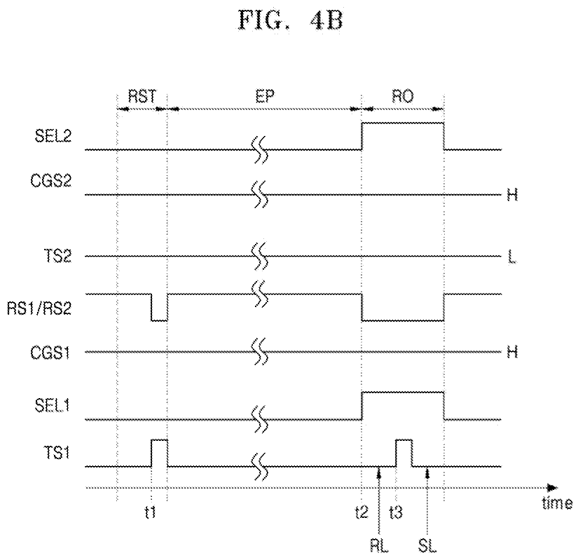

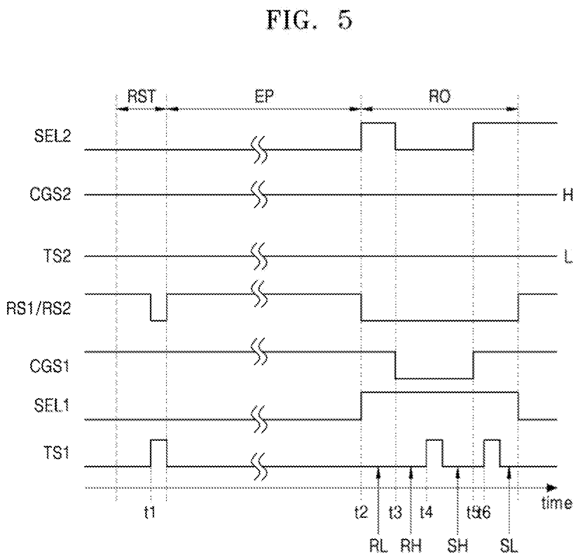

FIG. 4A is a view illustrating an LCG mode operation of a pixel array according to an example embodiment, and FIG. 4B is a timing diagram of FIG. 4A. FIGS. 4A and 4B illustrate operations of the first pixel PX1 and the second pixel PX2 when a pixel signal is readout from the first pixel PX1.

Referring to FIGS. 4A and 4B, the gain control transistors CGX1 and CGX2 of the first pixel PX1 and the second pixel PX2 may be turned on in response to the gain control signals CGS1 and CGS2 at an inactive level, e.g., a high level H. Therefore, the first pixel PX1 and the second pixel PX2 may operate in the LCG mode. The transmission transistor TX2 of the second pixel PX2 may be turned off in response to the transmission control signal TS2 at an inactive level, e.g., a low level L.

The reset transistors RX1 and RX2 of the first pixel PX1 and the second pixel PX2 may be turned on in response to the reset control signals RS1 and RS2 at high levels in a reset period RST, and the pixel power voltage VDDP may be applied to the first floating diffusion nodes FD11 and FD21 and the second floating diffusion nodes FD12 and FD22 so that the first floating diffusion nodes FD11 and FD21 and the second floating diffusion nodes FD12 and FD22 may be reset. The “reset” of the first floating diffusion nodes FD11 and FD21 and the second floating diffusion nodes FD12 and FD22 means that charges stored (accumulated) in the first floating diffusion nodes FD11 and FD21 and the second floating diffusion nodes FD12 and FD22 are discharged.

At a point in time t1, the transmission control signal TS1 applied to the first pixel PX1 may be transited from an inactive level, e.g., a low level, to an active level, e.g., a high level. The first transmission transistor TX1 is turned on in response to the transmission control signal TS1 so that charges left in the photoelectric conversion element PD1 may be transmitted (discharged) to the first floating diffusion node FD11. Then, the first transmission transistor TX1 is turned off in response to the transmission control signal TS1 at a low level and the reset transistors RX1 and RX2 are turned on so that the charges of the first floating diffusion node FD11 may be discharged.

Charge generating and accumulating operations in accordance with light incident from the photoelectric conversion device PD1 may start. In an exposure period EP, charge generating and accumulating operations may be performed by the photoelectric conversion device PD1. Specifically, the charge generating and accumulating operations may be performed by the photoelectric conversion device PD1 until the selection transistor SX1 is turned on at a point in time t2.

At the point in time t2, the selection transistor SX1 of the first pixel PX1 may be turned on in response to the selection signal SEL1 at a high level. The selection transistor SX1 may be in a turn-on state in a readout period RO (which may be referred to as a horizontal readout period). At this time, the selection transistor SX2 of the second pixel PX2 may be turned on in response to the selection signal SEL2 at a high level. Thus, in the readout period RO of the first pixel PX1, the selection transistors SX1 and SX2 of the first pixel PX1 and the second pixel PX2 may be turned on. In the readout period RO, the reset transistors RX1 and RX2 may be turned off.

Because the selection transistors SX1 and SX2 of the first pixel PX1 and the second pixel PX2 are turned on, the pixel signals may be output to the column line CL. The pixel signal output from the first pixel PX1 and the pixel signal output from the second pixel PX2 may be simultaneously output to the column line CL.

At a point in time t3, the transmission transistor TX1 may be turned on in response to the transmission control signal TS1 at a high level. In the exposure period EP, the charges generated by the photoelectric conversion element PD1 may be transmitted to the first floating diffusion node FD11. Because the first floating diffusion node FD11 is connected to the second floating diffusion node FD12 and the first and second floating diffusion nodes FD21 and FD22 of the second pixel PX2, the charges may be stored in the first and second floating diffusion nodes FD11, FD12, FD21, and FD22 of the first pixel PX1 and the second pixel PX2, and the first and second floating diffusion nodes FD11, FD12, FD21, and FD22 may have the same voltage.

In the readout period RO, the driving transistors DX1 and DX2 of the first pixel PX1 and the second pixel PX2 may output the pixel signals in accordance with the voltages of the first and second floating diffusion nodes FD11 and FD12, e.g., a first pixel voltage Vpx1 and a second pixel voltage Vpx2. Because the selection transistors SX1 and SX2 of the first pixel PX1 and the second pixel PX2 are turned on, the first pixel voltage Vpx1 and the second pixel voltage Vpx2 may be output to the column line CL.

Because the voltages of the first and second floating diffusion nodes FD11, FD12, FD21, and FD22 are the same, the first pixel voltage Vpx1 may be the same as the second pixel voltage Vpx2. However, due to characteristic deviation between the driving transistor DX1 of the first pixel PX1 and the driving transistor DX2 of the second pixel PX2, the first pixel voltage Vpx1 may be different from the second pixel voltage Vpx2. In the column line CL, the first pixel voltage Vpx1 and the second pixel voltage Vpx2 may be averaged, an average pixel signal corresponding to an average value of the first pixel voltage Vpx1 and the second pixel voltage Vpx2 may be provided to the CDS circuit (142 of FIG. 1), and the average pixel signal may be sampled by the CDS circuit 142.

As described above with reference to FIG. 1, the pixel signal may include the reset signal and the image signal, and the CDS circuit (142 of FIG. 1) connected to the column line CL1 may sample the reset signal and the image signal by sampling the pixel signal twice by the CDS method. After a reset signal RL (a reset signal in the LCG mode, which may be referred to as an LCG reset signal hereinafter) is sampled before the point in time t3 and the transmission transistor TX1 is toggled at the point in time t3, an image signal SL (an image signal in the LCG mode, which may be referred to as an LCG image signal hereinafter) may be sampled.

As described above, in the pixel array 110a, due to characteristic deviation between the driving transistors DX1 and DX2 of the pixels (e.g., the first pixel PX1 and the second pixel PX2), output deviation between the pixels may occur. For example, although the first floating diffusion node FD11 of the first pixel PX1 and the first floating diffusion node FD21 of the second pixel PX2 have the same voltage, deviation may occur between the first pixel voltage Vpx1 and the second pixel voltage Vpx2 output from the first pixel PX1 and the second pixel PX2. The output deviation between the pixels may result in noise in an image generated by the image sensor (100 of FIG. 1), which may be referred to as pixel response non-uniformity (PRNU).

However, as described above with reference to FIGS. 4A and 4B, when the pixel array 110a according to an example embodiment operates in the LCG mode, the floating diffusion nodes of at least two pixels connected to the same column line, e.g., the first pixel PX1 and the second pixel PX2, are connected to each other. When a pixel signal is read from one pixel, a pixel signal is output from at least another pixel connected to the pixel, and at least two pixel signals are averaged so that an averaged pixel signal is sampled. Therefore, the PRNU may be reduced and high light SNR may improve. Therefore, picture quality of the image generated by the image sensor 100 in the LCG mode may improve.

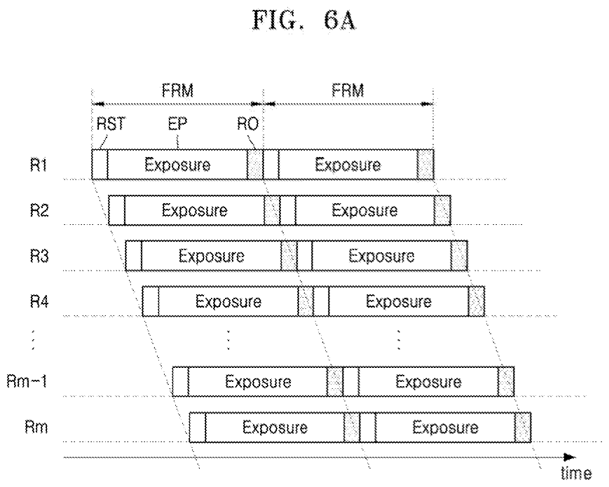

FIG. 5 is a timing diagram of a pixel array according to an example embodiment. FIG. 5 illustrates an intra-scene dual conversion gain (DCG) mode operation, in which a pixel (e.g., the first pixel PX1 of the pixel array (110a of FIG. 3A)) operates in the LCG mode and the HCG mode in a readout period of one frame.

Referring to FIGS. 3A and 5, the gain control transistor CGX2 of the second pixel PX2 may be turned on in response to the gain control signal CGS1 at a high level, and the transmission transistor TX2 of the second pixel PX2 may be turned off in response to the transmission control signal TS1 at a high level.

At the point in time t1, the first transmission transistor TX1 of the first pixel PX1 is turned on in response to the transmission control signal TS1 at a high level so that the charges left in the photoelectric conversion element PD1 may be transmitted (discharged) to the first floating diffusion node FD11. Then, the first transmission transistor TX1 is turned off in response to the transmission control signal TS1 at a low level, and the reset transistors RX1 and RX2 are turned on so that the charges of the first floating diffusion node FD11 may be discharged.

Charge generating and accumulating operations in accordance with light incident from the photoelectric conversion device PD1 may start. In the exposure period EP, the charge generating and accumulating operations may be performed by the photoelectric conversion device PD1.

At the point in time t2, the selection transistor SX1 of the first pixel PX1 may be turned on in response to the selection signal SEL1 at a high level. The selection transistor SX1 of the first pixel PX1 may be in a turn-on state in a readout period RO (which may be referred to as a horizontal readout period). The reset transistors RX1 and RX2 may be turned off in response to the reset control signals RS1 and RS2 at a low level in the readout period RO. At the point in time t2, the selection transistor SX2 of the second pixel PX2 may be turned on in response to the selection signal SEL2 at a high level. The gain control transistor CGX1 of the first pixel PX1 may be turned on in response to the gain control signal CGS1 at a high level. The first pixel PX1 may be in the LCG mode, and the first pixel PX1 and the second pixel PX2 may respectively output the first pixel voltage Vpx1 and the second pixel voltage Vpx2 corresponding to the reset signals. After the point in time t2, the LCG reset signal RL may be sampled in the LCG mode. The sampled LCG reset signal RL may correspond to an average of the reset signals of the first pixel PX1 and the second pixel PX2.

At the point in time t3, the gain control transistor CGX1 of the first pixel PX1 may be turned off in response to the gain control signal CGS1 at a low level. Therefore, the mode of the first pixel PX1 may change into the HCG mode. The selection transistor SX2 of the second pixel PX2 may be turned off in response to the selection signal SEL2 at a low level. Therefore, the first pixel PX1 may output the first pixel voltage Vpx1 corresponding to the reset signal to the column line CL.

After the point in time t3, in the HCG mode, an HCG reset signal RH may be sampled. The sampled HCG reset signal RH may correspond to the reset signal output from the first pixel PX1.

At a point in time t4, the transmission transistor TX1 may be turned on in response to the transmission control signal TS1 at a high level. In the exposure period EP, the charges generated by the photoelectric conversion element PD1 may be transmitted to the first floating diffusion node FD11. The driving transistor DX1 of the first pixel PX1 may generate a pixel signal in accordance with the voltage of the first floating diffusion node FD11, i.e., an image signal. The first pixel PX1 may generate the first pixel voltage Vpx1 corresponding to the image signal. The first pixel voltage Vpx1 corresponding to the image signal may be output to the column line CL.

After the point in time t4, in the HCG mode, an HCG image signal SH may be sampled. The sampled HCG image signal SH is the image signal output from the first pixel PX1.

At a point in time t5, the gain control transistor CGX1 of the first pixel PX1 may be turned on in response to the gain control signal CGS1 at a high level. Therefore, the first and second floating diffusion nodes FD11, FD12, FD21, and FD22 of the first pixel PX1 and the second pixel PX2 may be connected to one another. Capacitance of the first floating diffusion node FD11 of the first pixel PX1 may increase. A mode of the first pixel PX1 may change into the LCG mode. At the point in time t5, the selection transistor SX2 of the second pixel PX2 may be turned on in response to the selection signal SEL2 at a high level.

At a point in time t6, the transmission transistor TX1 may be turned on in response to the transmission control signal TS1 at a high level. The charges left in the photoelectric conversion element PD1 may be transmitted to the first floating diffusion node FD11.

After a point in time t6, in the LCG mode, an LCG image signal SL may be sampled. At this time, the first pixel PX1 and the second pixel PX2 may respectively output the first pixel voltage Vpx1 and the second pixel voltage Vpx2 corresponding to image signals. Therefore, the LCG image signal SL may correspond to an average of image signals of the first pixel PX1 and the second pixel PX2.

As described above, in the readout period RO, the LCG reset signal RL, the HCG reset signal RH, the HCG image signal SH, and the LCG image signal SL may be sequentially sampled for the plurality of pixels PX of the pixel array 110a. An LCG image may be generated based on the LCG reset signal RL and the LCG image signal SL of each of the plurality of pixels PX, and an HCG image may be generated based on the HCG reset signal RH and the HCG image signal SH of each of the plurality of pixels PX. The signal processor (170 of FIG. 1) of the image sensor (100 of FIG. 1) or a signal processor of an external host may generate an image in a high dynamic range by merging the LCG image with the HCG image.

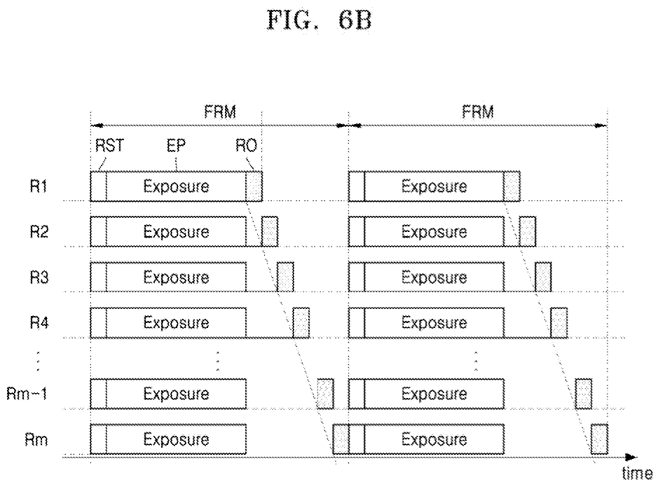

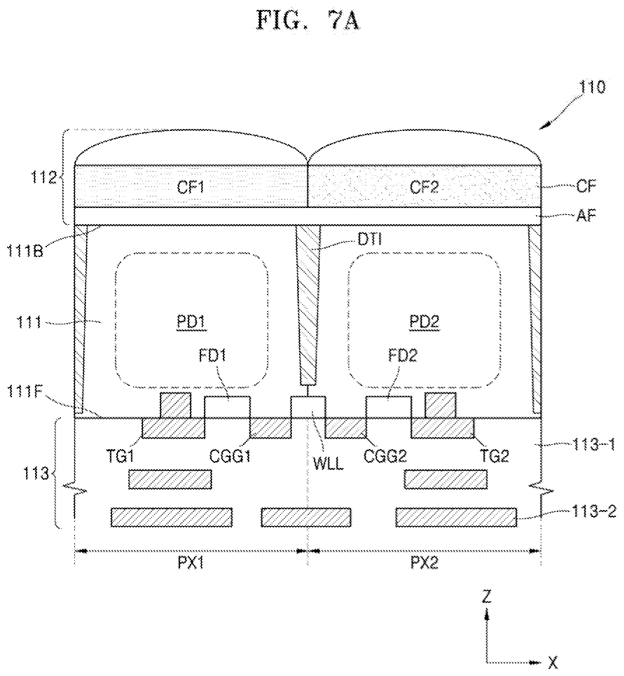

FIGS. 6A and 6B are timing diagrams illustrating operations in accordance with shutter methods of a pixel array 110 according to an example embodiment.

Referring to FIG. 6A, the pixel array (110 of FIG. 1) may operate by a rolling shutter method. In one frame period FRM, in the reset period RST, the exposure period EP, and the readout period RO, a reset operation, a charge generating and accumulating operation, and a readout operation may be performed on each of a plurality of rows, e.g., the first to m^{th} rows R1 to Rm and the reset operation, an exposure operation, and the readout operation may be sequentially performed on the first to m^{th} rows R1 to Rm. The readout periods RO of the first to m^{th} rows R1 to Rm do not overlap.

Referring to FIG. 6B, the pixel array (110 of FIG. 1) may operate by a global shutter method. In one frame period FRM, in the reset period RST, the exposure period EP, and the readout period RO, the reset operation, the exposure operation, and the readout operation may be performed on each of the plurality of rows, e.g., the first to m^{th} rows R1 to Rm and the reset operation and the charge generating and accumulating operation may be simultaneously performed on the first to m^{th} rows R1 to Rm. The readout operation may be sequentially performed on the first to m^{th} rows R1 to Rm and the readout periods RO of the first to m^{th} rows R1 to Rm do not overlap.

In the readout periods RO of FIGS. 6A and 6B, operations of two pixels PX included in two adjacent rows (e.g., the first row R1 and the second row R2, the third row R3 and the fourth row R4, or the (m-1)th row Rm-1 and the mth row Rm) and connected to the same column line may be the same as those of the first pixel PX1 and the second pixel PX2 of FIG. 4A, which are described with reference to FIG. 4B or 5.

For example, when the readout operation is performed on the first row R1, the operations of the first pixel PX1 in the first row R1 and the second pixel PX2 in the second row R2 may be the same as those of the first pixel PX1 and the second pixel PX2 of FIG. 4A. When the readout operation is performed on the second row R2, the operations of the first pixel PX1 in the first row R1 and the second pixel PX2 in the second row R2 may be the same as those of the first pixel PX1 and the second pixel PX2 of FIG. 4A. When the readout operation is performed on the third row R3, the operations of the third pixel PX3 in the third row R3 and the fourth pixel PX4 in the fourth row R4 may be the same as those of the first pixel PX1 and the second pixel PX2 of FIG. 4A. When the readout operation is performed on the fourth row R4, the operations of the third pixel PX3 in the third row R3 and the fourth pixel PX4 in the fourth row R4 may be the same as those of the first pixel PX1 and the second pixel PX2 of FIG. 4A.

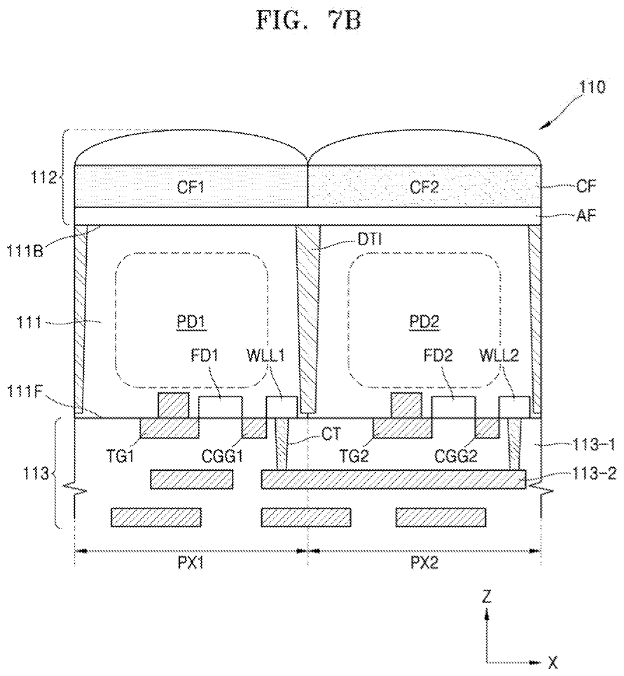

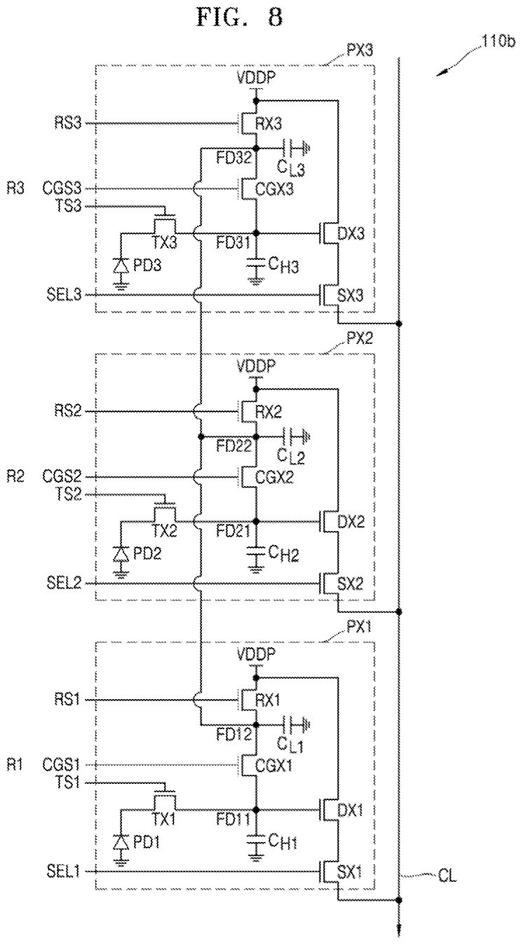

FIGS. 7A and 7B are vertical cross-sectional views in accordance with implementations of a pixel array 110 according to an example embodiment.

Referring to FIG. 7A, the pixel array 110 may include a semiconductor substrate 111 (hereinafter, referred to as a substrate) having a first surface 111B and a second surface 111F facing away from each other, an incident layer 112, e.g., a light-incident layer, arranged on the first surface 111B of the semiconductor substrate 111, and a wiring layer 113 (which may be referred to as a wiring structure) arranged on the second surface 111F of the semiconductor substrate 111.

The semiconductor substrate 111 may include, e.g., at least one selected from silicon (Si), germanium (Ge), SiGe, silicon carbide (SiC), gallium arsenide (GaAs), indium arsenide (InAs), and indium phosphide (InP). In an example embodiment, the semiconductor substrate 111 may be doped with first conductivity type impurities. For example, the first conductivity type may be a p type, and the first conductivity type impurities may be boron (B)

A deep trench isolator (DTI) may be arranged in the semiconductor substrate 111. The DTI may reach the second surface 111F from the first surface 111B through the semiconductor substrate 111. The DTI arranged between the first pixel PX1 and the second pixel PX2 may extend from the first surface 111B to the second surface 111F, and may be apart from the second surface 111F. The DTI may include, e.g., at least one of a silicon oxide layer, a hafnium oxide layer, an aluminum oxide layer, and a polysilicon layer doped with impurities. The DTI may have a single layer or multilayer structure.

The DTI may separate pixels, e.g., the first pixel PX1 and the second pixel PX2. The DTI may prevent crosstalk between pixels, e.g., the first pixel PX1 and the second pixel PX2.

The photoelectric conversion elements PD1 and PD2 may be arranged in the semiconductor substrate 111. Each of the photoelectric conversion elements PD1 and PD2 may include a region doped with second conductivity type impurities opposite to the first conductivity type impurities. For example, a second conductivity type may be an n type, and the second conductivity type impurities may include phosphorus (P), arsenic (As), bismuth (Bi), and/or antimony (Sb). The region doped with the second conductivity type impurities may configure the photoelectric conversion elements PD1 and PD2 by forming a PN junction with a neighboring region doped with the first conductivity type impurities of the semiconductor substrate 111.

The first surface 111B of the semiconductor substrate 111 may be an incident surface of light, and light may be incident through the incident layer 112 and the first surface 111B of the semiconductor substrate 111. The incident layer 112 may include a micro-lens ML and a plurality of color filters CF. In an example embodiment, an antireflection layer AF may be arranged between the first surface 111B of the semiconductor substrate 111 and the plurality of color filters CF. In an example embodiment, the antireflection layer AF, the plurality of color filters CF, and the micro-lens ML may be sequentially stacked on the first surface 110B of the semiconductor substrate 111.

The plurality of color filters CF may transmit light components of specific spectrum bands, that is, light components of specific colors. The plurality of color filters CF may configure a color filter array. In an example embodiment, the color filter array may have a Bayer pattern. The plurality of color filters CF may include a red filter, a blue filter, and two green filters, the red filter, the blue filter, and the two green filters may be arranged in 2×2, and the two green filters may be diagonally arranged. In an example embodiment, the plurality of color filters CF may include two red filters arranged in 2×2, a blue filter, a green filter, and a white filter. However, the plurality of color filters may include filters of other combined colors. For example, the plurality of color filters may include a yellow filter, a cyan filter, and a green filter.

A first color filter CF1 may be arranged on the first pixel PX1, and a second color filter CF2 may be arranged on the second pixel PX2. The first color filter CF1 and the second color filter CF2 may transmit light components of the same color or different colors. In accordance with a color of light transmitted by a color filter, a color that may be sensed by a corresponding pixel (the first pixel PX1 or the second pixel PX2) may be determined.

A floating diffusion region, e.g., first and second floating diffusion regions FD1 and FD2, may be adjacent to the second surface 111F of the semiconductor substrate 111. The first and second floating diffusion regions FD1 and FD2 may be doped with the second conductivity type impurities.

In the wiring layer 113, a gate terminal, e.g., transmission gates TG1 and TG2 and gain control gates CGG1 and CGG2 of transistors, may be adjacent to the second surface 111F of the semiconductor substrate 111. The transmission gates TG1 and TG2 and the gain control gates CGG1 and CGG2 may be a gate terminal of the transmission transistors (TX1 and TX2 of FIG. 3A) and the gain control transistors (CGX1 and CGX2 of FIG. 3A).

The transmission gates TG1 and TG2 and the gain control gates CGG1 and CGG2 may be adjacent to the first and second floating diffusion regions FD1 and FD2. In the semiconductor substrate 111, a well region WLL may be adjacent to the gain control gates CGG1 and CGG2, and may be shared by the first pixel PX1 and the second pixel PX2. The well region WLL may be a drain terminal of the gain control transistors CGX1 and CGX2 and the second floating diffusion regions FD12 and FD22 of the first pixel PX1 and the second pixel PX2. In FIG. 7A, the second floating diffusion regions FD12 and FD22 of the first pixel PX1 and the second pixel PX2 may be connected to each other by the well region WLL that is shared by the first pixel PX1 and the second pixel PX2.

The wiring layer 113 may include conductive lines 113-2 arranged in an interlayer insulating layer 113-1, each of which is a multilayer. The conductive lines 113-2 may transmit control signals supplied to the respective transistors or signals between the pixels and the outside. The conductive lines 113-2 may be formed by patterning a conductive material including a metal material such as copper (Cu) or aluminum (Al), and may extend in a first direction, e.g., an X axis direction and a second direction, e.g., a Y axis direction.

Referring to FIG. 7B, in the semiconductor substrate 111, well regions WLL1 and WLL2 may be adjacent to the gain control gates CGG1 and CGG2, and may act as a drain terminal of the gain control transistors CGX1 and CGX2 and the second floating diffusion regions FD12 and FD22 of the first pixel PX1 and the second pixel PX2. The well regions WLL1 and WLL2 may be connected to each other by contacts CT and the conductive line 113-1. As described above, the second floating diffusion regions FD12 and FD22 of the first pixel PX1 and the second pixel PX2 may be connected to one another by the contacts CT and the conductive line 113-1 formed in the wiring layer 113.

FIG. 8 illustrates an implementation of a pixel array 110b according to an example embodiment.

Referring to FIG. 8, in the pixel array 110b, respective second floating diffusion nodes FD12, FD22, and FD32 of the first pixel PX1, the second pixel PX2, and the third pixel PX3 connected to the same column line CL and arranged in different rows, e.g., the first to third rows R1, R2, and R3, may be electrically connected to one another.

In the LCG mode, gain control transistors CGS1, CGS2, and CGS3 may be turned on so that first floating diffusion nodes FD11, FD21, and FD31 and the second floating diffusion nodes FD12, FD22, and FD32 may be electrically connected to one another. In the LCG mode, during a readout operation of the first pixel PX1, operations of the first pixel PX1 and the second pixel PX2 are the same as described with reference to FIGS. 4A and 4B, and an operation of the third pixel PX3 is the same as that of the second pixel PX2. Respective selection transistors SX1, SX2, and SX3 of the first pixel PX1, the second pixel PX2, and the third pixel PX3 are turned on so that the first pixel PX1, the second pixel PX2, and the third pixel PX3 may respectively output pixel signals, the pixel signals of the first pixel PX1, the second pixel PX2, and the third pixel PX3 may be averaged in the column line CL, and an average pixel signal may be analog-to-digital converted by the ADC (140 of FIG. 1), and may be converted into a pixel value for the first pixel PX1.

With reference to FIG. 8, it has been described that the second floating diffusion nodes FD12, FD22, and FD32 of three pixels, e.g., the first pixel PX1, the second pixel PX2, and the third pixel PX3 are electrically connected to one another and, when a readout operation is performed on one pixel in the LCG mode, the first pixel PX1, the second pixel PX2, and the third pixel PX3 respectively output the pixel signals. However, this may be varied. For example, second floating diffusion nodes of four or more pixels may be connected to the same column line CL and connected to one another, and a readout operation is performed on one pixel in the LCG mode, the four or more pixels may respectively output pixel signals, and the pixel signals may be averaged.

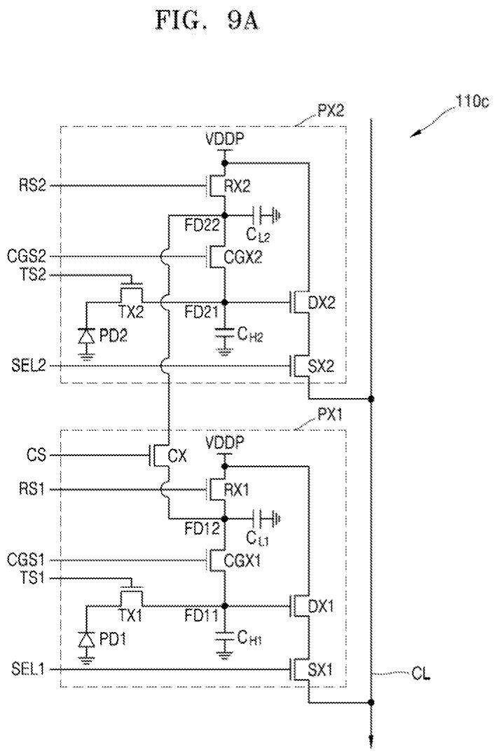

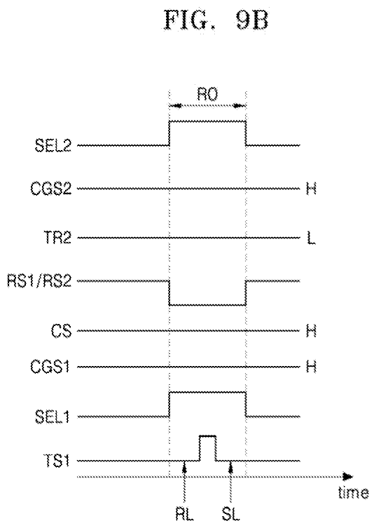

FIG. 9A illustrates an implementation of a pixel array 110a according to an example embodiment and FIG. 9B is a timing diagram of the pixel array 110a of FIG. 9A. FIG. 9A illustrates a modification of the pixel array 110a of FIG. 3A. Therefore, previously given description will not be given again, and description will be given based on differences.

Referring to FIG. 9A, the pixel PX1 may further include a connection transistor CX connected between, e.g., controlling the connection between, the second floating diffusion nodes F12 and FD22. The connection transistor CX may be turned on or turned off in response to a connection control signal CS provided by the row driver (120 of FIG. 1).

FIG. 9B illustrates control signals applied to the first pixel PX1 and the second pixel PX2 in the LCG mode in the readout period RO of the first pixel PX1.

Referring to FIG. 9B, in the LCG mode, the connection transistor CX and the gain control transistors CGX1 and CGX2 may be turned on in response to the connection control signal CS and the gain control signals CGS1 and CGS2 at high levels. Therefore, the first and second floating diffusion nodes FD11, FD12, FD21, and FD22 of the first pixel PX1 and the second pixel PX2 may be connected to one another and may have the same voltage level.

In response to the selection signals SEL1 and SEL2 at high levels, the selection transistors SX1 and SX2 of the first pixel PX1 and the second pixel PX2 may be turned on. Therefore, the first pixel PX1 and the second pixel PX2 may respectively output the pixel signals. The pixel signal of the first pixel PX1 and the pixel signal of the second pixel PX2 may be averaged in the column line CL.

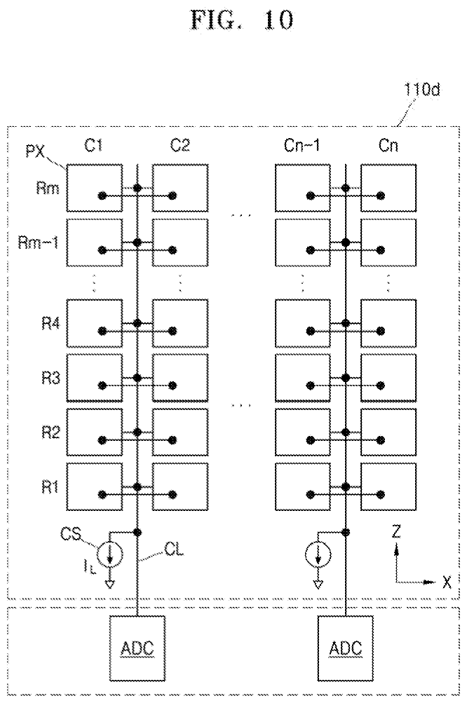

FIG. 10 illustrates a pixel array 110d according to an example embodiment. The pixel array 110d of FIG. 10 may be applied to the image sensor 100 of FIG. 1 as the pixel array 110.

Referring to FIG. 10, the pixel array 110d may include a plurality of pixels PX arranged in a matrix. The plurality of pixels PX may be arranged in a plurality of rows and columns. For example, the plurality of pixels PX may be arranged in the first to m^{th} rows R1 to Rm (m is a positive integer) and the first to n^{th} columns C1 to Cn (n is a positive integer).

Pixels PX arranged in at least two adjacent columns may be connected to the same column line CL. For example, pixels PX arranged in a first column CL1 and a second column CL2 may be connected to the same column line CL. However, this may be varied, and pixels arranged in three or more columns may be connected to the same column line CL.

At least two pixels PX arranged in the same row and connected to the same column line CL may be electrically connected through an internal element. For example, referring to FIG. 10, two pixels PX respectively arranged in the first column C1 and the second column C2 may be connected to each other, and two pixels PX respectively arranged in the (n-1)^{t} column Cn-1 and the n^{th} column Cn may be connected to each other. As described above, each two pixels PX may be connected to each other, and may share floating diffusion nodes.

As described above with reference to FIGS. 6A and 6B, the plurality of columns may be sequentially driven and the readout operation may be sequentially performed on the plurality of columns. In the present example embodiment, because pixels PX arranged in two columns are connected to the same column line, the readout operation may be sequentially performed on the plurality of columns and, when the readout operation is performed on one column, the readout operation may be sequentially performed on the pixels PX arranged in the two columns.

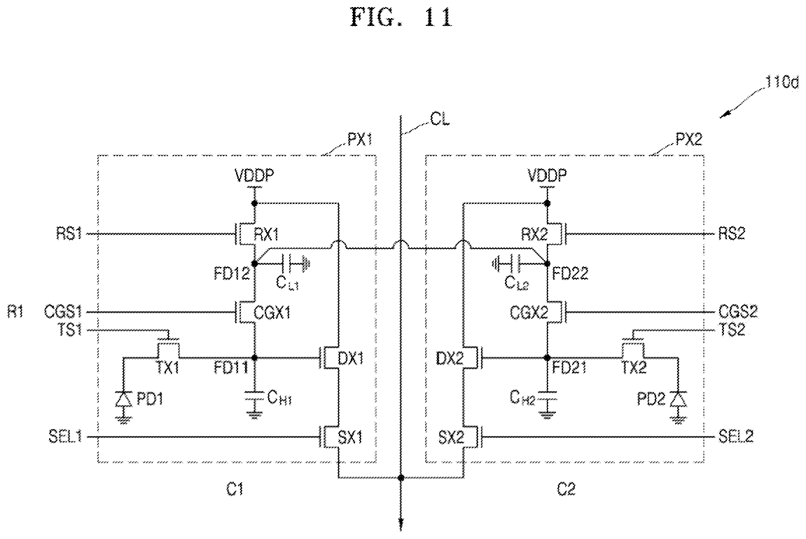

FIG. 11 illustrates an implementation of a pixel array 110d according to an example embodiment. FIG. 11 is an implementation of the pixel array 110d of FIG. 10. For convenience sake, two pixels PX1 and PX2 are illustrated.

Referring to FIG. 11, the pixel array 110d may include the first pixel PX1 and the second pixel PX2 respectively arranged in the first column C1 and the second column C2. The first pixel PX1 and the second pixel PX2 may be connected to the same column line CL, and may also be internally connected to each other.

The first pixel PX1 may include a photoelectric conversion element PD1 and a plurality of transistors, e.g., a transmission transistor TX1, a reset transistor RX1, a gain control transistor CGX1, a driving transistor DX1, and a selection transistor SX1.

The second pixel PX2 may include a photoelectric conversion element PD2 and a plurality of transistors, e.g., a transmission transistor TX2, a reset transistor RX2, a gain control transistor CGX2, a driving transistor DX2, and a selection transistor SX2.

A second floating diffusion node FD22 of the second pixel PX2 may be connected to a second floating diffusion node FD12 of the first pixel PX1. In an example embodiment, as described above with reference to FIG. 9A, the first pixel PX1 or the second pixel PX2 may further include the connection transistor CX (not shown in FIG. 11), and the connection transistor CX may be turned on in the LCG mode.

In the LCG mode, when the gain control transistor CGX1 of the first pixel PX1 and the gain control transistor CGX2 of the second pixel PX2 are turned on, the first floating diffusion node FD11 and the second floating diffusion node FD12 of the first pixel PX1 and the first floating diffusion node FD21 and the second floating diffusion node FD22 of the second pixel PX2 may be electrically connected.

In the LCG mode, the selection transistors SX1 and SX2 of the first pixel PX1 and the second pixel PX2 are turned on so that the first pixel PX1 and the second pixel PX2 may respectively output the pixel signals, the pixel signals of the first pixel PX1 and the second pixel PX2 may be averaged in the column line CL, and the average pixel signal may be analog-to-digital converted by the ADC (140 of FIG. 1).

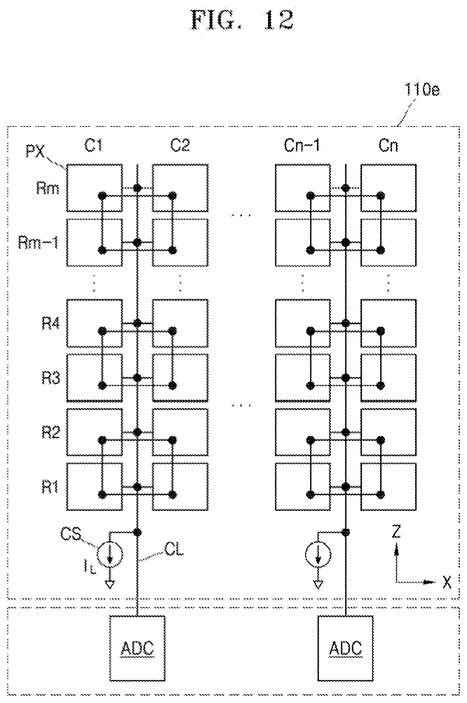

FIG. 12 illustrates a pixel array 110e according to an example embodiment. The pixel array 110e of FIG. 12 may be applied to the image sensor 100 of FIG. 1 as the pixel array 110.

Referring to FIG. 12, the pixel array 110e may include a plurality of pixels PX arranged in a matrix.

Pixels arranged in at least two adjacent columns may be connected to the same column line CL. For example, pixels PX arranged in a first column CL1 and a second column CL2 may be connected to the same column line CL. However, this may be varied, and pixels arranged in three or more columns may be connected to the same column line CL.

At least four pixels PX arranged in at least two adjacent rows and connected to the same column line CL may be electrically connected to one another through internal elements, and may share floating diffusion nodes.

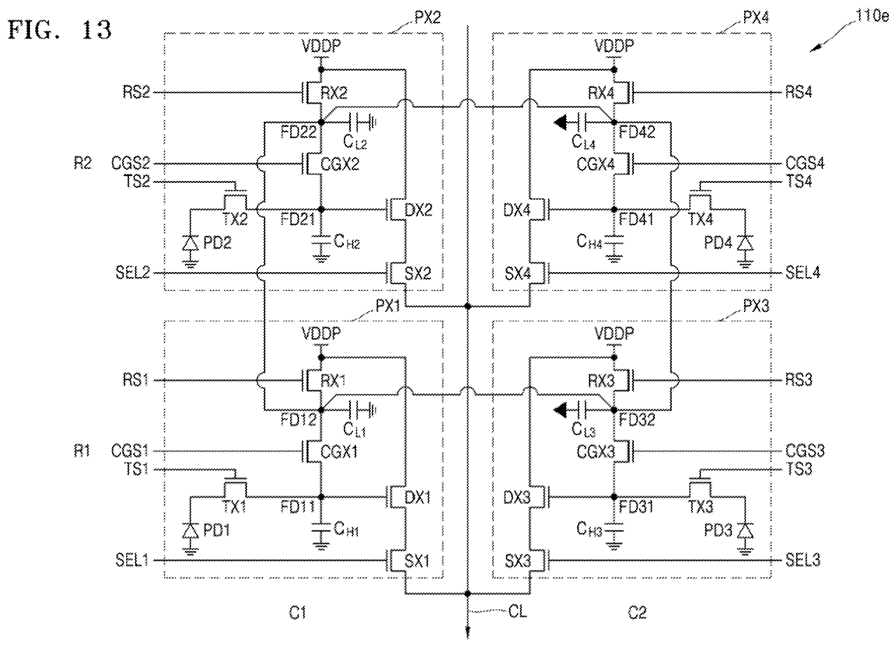

FIG. 13 illustrates an implementation of a pixel array 110e according to an example embodiment. FIG. 13 is an implementation of the pixel array 110e of FIG. 12. For convenience sake, two pixels PX1 and PX2 are illustrated.

Referring to FIG. 13, the pixel array 110e may include first to fourth pixels PX1 to PX4 arranged in a first column C1 and a second column C2 and a first row R1 and a second row R2 in a matrix. The first to fourth pixels PX1 to PX4 may be connected to the same column line CL and may be internally connected to one another.

The first to fourth pixels PX1 to PX4 may respectively include photoelectric conversion elements PD1, PD2, PD3, and PD4 and a plurality of transistors, e.g., transmission transistors TX1, TX2, TX3, and TX4, reset transistors RX1, RX2, RX3, and RX4, gain control transistors CGX1, CGX2, CGX3, and CGX4, driving transistors DX1, DX2, DX2, DX3, and DX4, and selection transistors SX1, SX2, SX3, and SX4.

Second floating diffusion nodes FD12, FD22, FD32, and FD42 of the first to fourth pixels PX1 to PX4 may be connected to one another. In an example embodiment, as described above with reference to FIG. 9A, at least one of the first to fourth pixels PX1 to PX4 may further include the connection transistor CX (not shown in FIG. 13), and the connection transistor CX may be turned on in the LCG mode.

In the LCG mode, when the gain control transistors CGX1, CGX2, CGX3, and CGX4 of the first to fourth pixels PX1 to PX4 are turned on, first floating diffusion nodes FD11, FD21, FD31, and FD41 and the second floating diffusion nodes FD12, FD22, FD32, and FD42 of the first to fourth pixels PX1 to PX4 may be electrically connected to one another.

In the LCG mode, the selection transistors SX1, SX2, SX3, and SX4 of the first to fourth pixels PX1 to PX4 are turned on so that the first to fourth pixels PX1 to PX4 may respectively output pixel signals, the pixel signals of the first to fourth pixels PX1 to PX4 may be averaged in the column line CL, and the average pixel signal may be analog-to-digital converted by the ADC (140 of FIG. 1).

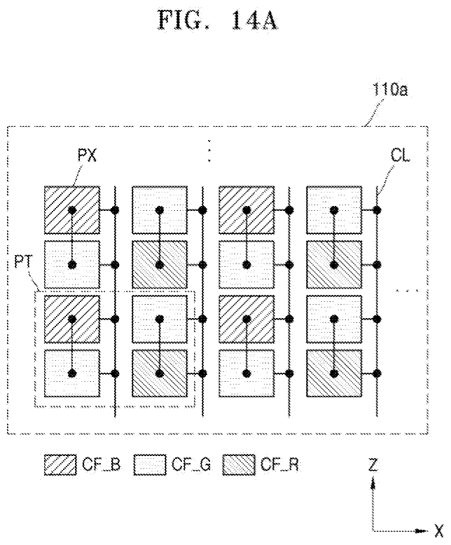

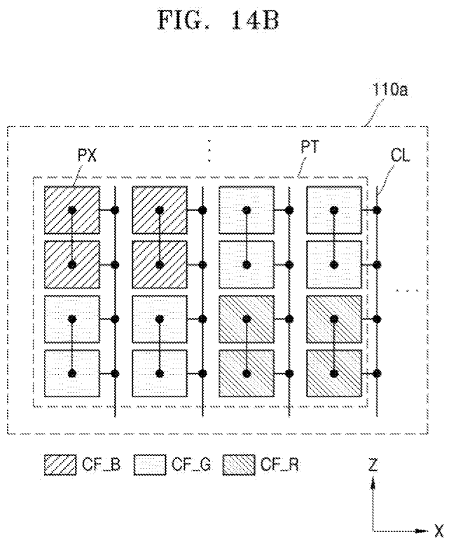

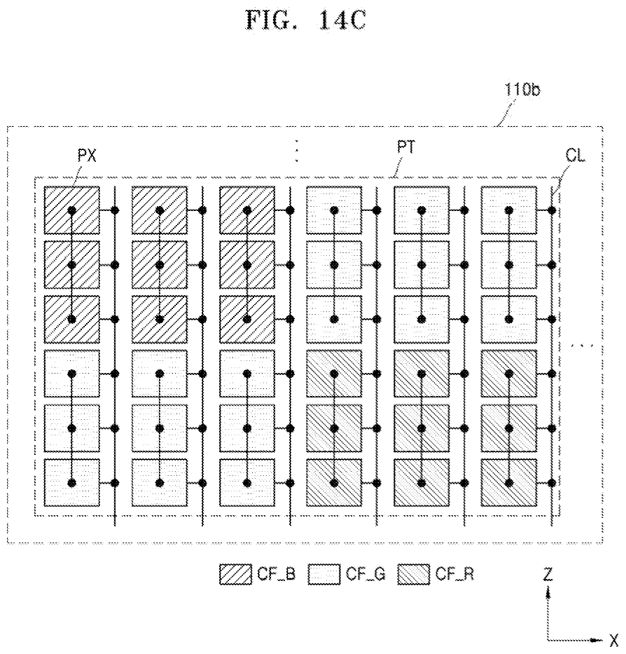

FIGS. 14A, 14B, and 14C illustrate color filters arranged in a pixel array according to an example embodiment.

Referring to FIG. 14A, in the pixel array 110a, at least two pixels PX arranged in two adjacent rows and connected to the same column line CL may be electrically connected to each other. A blue color filter CF_B, two green color filters CF_G, and a red color filter CF_R may be arranged in four pixels PX in a 2×2 matrix. A pattern PT of the color filters arranged in the four pixels PX in the 2×2 matrix may be referred to as the Bayer pattern, and the Bayer pattern may be repeated in a matrix in the pixel array 110a.

Referring to FIG. 14B, color filters of the same color may be arranged in the four pixels PX in the 2×2 matrix. Color filters of the same color may be arranged in two pixels PX electrically connected to each other. For example, each of the blue color filters CF_B, the green color filters CF_G, and the red color filters CF_R may be arranged in the four pixels PX in the 2×2 matrix. The green color filters CF_G may be diagonally arranged. A pattern PT of color filters arranged in 16 pixels PX in a 4×4 matrix may be referred to as a tetra pattern, and the tetra pattern may be repeated in a matrix in the pixel array 110a.

Referring to FIG. 14C, in the pixel array 110b, at least three pixels PX arranged in three adjacent rows and connected to the same column line CL may be electrically connected to one another. Color filters of the same color may be arranged in nine pixels PX in a 3×3 matrix. The color filters of the same color may be arranged in three pixels PX electrically connected to one another. For example, each of the blue color filters CF_B, the green color filters CF_G, and the red color filters CF_R may be arranged in the nine pixels PX in the 3×3 matrix. The green color filters CF_G may be diagonally arranged. A pattern PT of color filters arranged in 36 pixels PX in a 6×6 matrix may be referred to as a Nona pattern, and the Nona pattern may be repeated in a matrix in the pixel array 110b.

In FIGS. 14A to 14C, it is illustrated that the blue color filters CF_B, the green color filters CF_G, and the red color filters CF_R are arranged in the pixel array. However, a combination of the colors of the color filters may vary. For example, the blue color filters CF_B, the green color filters CF_G, the red color filters CF_R, and white color filters may be arranged in the pixel array. Alternatively, the blue color filters CF_B, yellow color filters CF_Y, and the red color filters CF_R may be arranged in the pixel array.

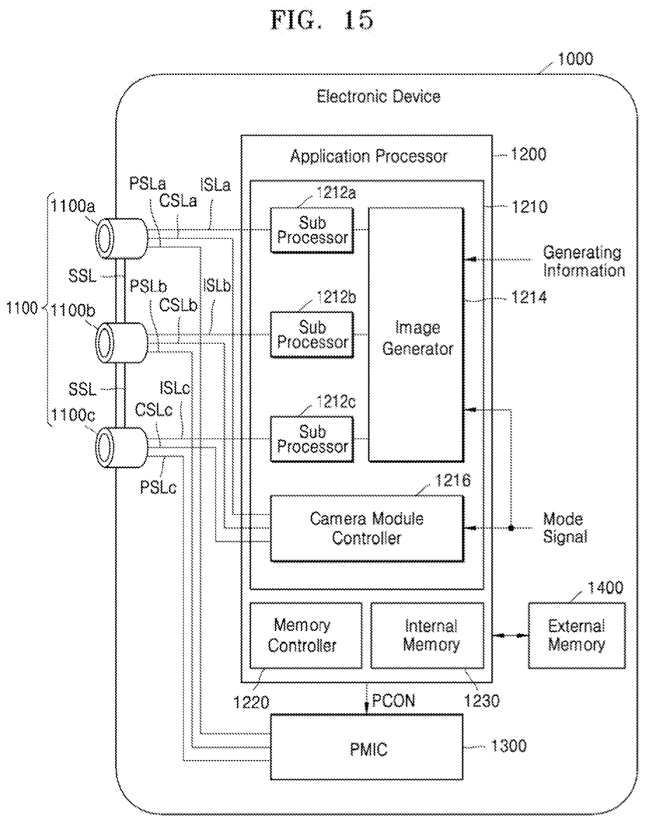

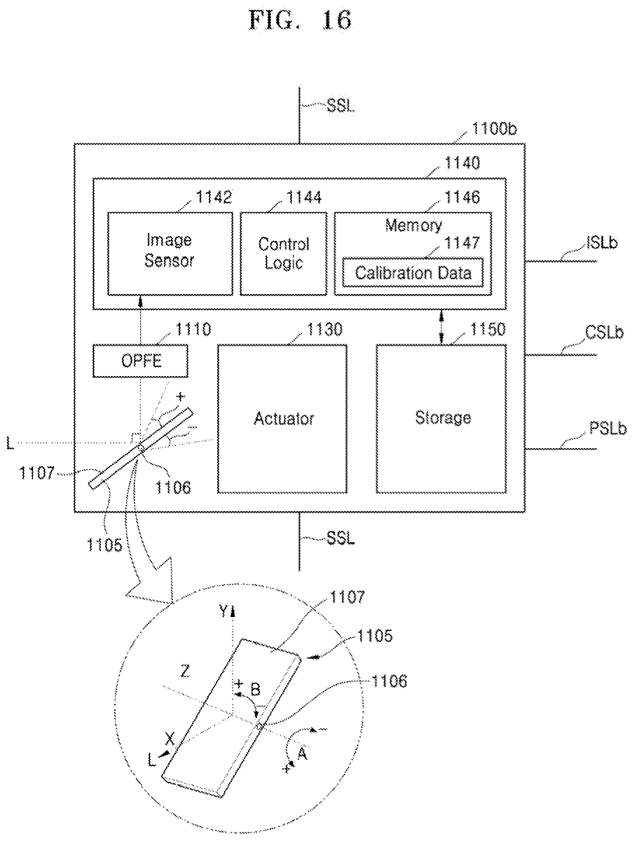

FIG. 15 illustrates an electronic device including a multi-camera module, and FIG. 16 is a detailed block diagram of the camera module of FIG. 15.

Referring to FIG. 15A, an electronic device 1000 may include a camera module group 1100, an application processor 1200, a power management integrated circuit (PMIC) 1300, and an external memory 1400.

The camera module group 1100 may include a plurality of camera modules 1100a, 1100b, and 1100c. Although FIG. 15A shows an embodiment in which three camera modules 1100a, 1100b, and 1100c are arranged, e.g., the camera module group 1100 may include two camera modules, or may include k (where k is a natural number greater than or equal to 4) camera modules.

Hereinafter, a detailed configuration of the camera module 1100b will be described in more detail with reference to FIG. 15B, and the following description may be equally applied to the other camera modules 1100a and 1100b.

Referring to FIG. 16, the camera module 1100b may include a prism 1105, an optical path folding element (OPFE) 1110, an actuator 1130, an image sensing device 1140, and a storage 1150.

The prism 1105 may include a reflective surface 1107 of a light reflecting material to change a path of light L incident from the outside.

In an example embodiment, the prism 1105 may change the path of the light L incident in a first direction X to a second direction Y perpendicular to the first direction X. The prism 1105 may rotate on a central axis 1106 of the reflective surface 1107 of the light reflecting material in an A direction or a B direction, thereby changing the path of the light L incident in the first direction X to the second direction Y perpendicular thereto. The OPFE 1110 may also move in a third direction Z perpendicular to the first direction X and the second direction Y.

In an example embodiment, the greatest rotation angle of the prism 1105 in the A direction may be less than 15 degrees in a +A direction, and may be greater than 15 degrees in a −A direction, as shown in FIG. 15B, but this may be varied.

In an example embodiment, the prism 1105 may move in a range of approximately 20 degrees or may move between 10 degrees and 20 degrees or between 15 degrees and 20 degrees in a +B or −B direction, and angles of movement may be the same as each other in the +B or −B direction or may be within a range of 1 degree.

In an example embodiment, the reflective surface 1107 of the light reflective material of the prism 1105 may move in the third direction (e.g., the Z direction) parallel to an extension direction of the central axis 1106.

In an example embodiment, the camera module 1100b may include two or more prisms, thereby variously changing the path of the light L incident in the first direction X to a second direction Y perpendicular to the first direction X, to the first direction X or the third direction Z, and then to the second direction Y again.

The OPFE 1110 may include, e.g., an optical lens including m (m is a natural number) groups. The m lenses may move in the second direction Y to change an optical zoom ratio of the camera module 1100b. For example, when a basic optical zoom ratio of the camera module 1100b is referred to as Z, and when m optical lenses included in the OPFE 1110 are moved, the optical zoom ratio of the camera module 1100b may be changed to 3Z, 5Z, or more.

The actuator 1130 may move the OPFE 1110 or an optical lens (hereinafter, referred to as an optical lens) to a specific position. For example, the actuator 1130 may adjust a position of the optical lens for accurate sensing so that an image sensor 1142 (described further below) is located at a focal plane of the optical lens.

The image sensing device 1140 may include the image sensor 1142, a control logic 1144, and a memory 1146. The image sensor 1142 may sense an image of a sensing target by using the light L provided through the optical lens.

The pixel array described above with reference to FIGS. 1 to 14B may be applied to the image sensor 1142. A plurality of pixels connected to the same color line may be connected to one another and may share floating diffusion nodes in the LCG mode. When a pixel signal of one of the plurality of pixels is read in the LCG mode, the plurality of pixels may respectively output pixel signals. The pixel signals output from the plurality of pixels may be averaged and the average pixel signal may be analog-to-digital converted and may be generated as a pixel value for a pixel to be read. Therefore, the noise caused by the characteristic deviation between the driving transistors of the pixels, for example, the PRNU may be reduced. Therefore, the picture quality of the image generated in the LCG mode may improve.

The control logic 1144 may control operations of the camera module 1100b, and may process the sensed image. For example, the control logic 1144 may control the operations of the camera module 1100b according to a control signal provided through a control signal line CSLb, and may extract image data (e.g., face, arms, legs, and the like) from an image corresponding to a specific image in the sensed image, or perform image processing such as noise removal.

The memory 1146 may store information, such as calibration data 1147 for the operation of the camera module 1100b. The calibration data 1147 may be information for the camera module 1100b to generate image data by using the light L provided from the outside and may include, e.g., information on a degree of rotation, information on a focal length, information on an optical axis, and the like. When the camera module 1100b includes a multi-state camera whose focal length is changed according to a position of the optical lens, the calibration data 1147 may include information on focal length values for each position (or state) of the optical lens and on auto focusing.

The storage 1150 may store image data sensed by the image sensor 1142. The storage 1150 may be arranged outside the image sensing device 1140, and may be implemented in a stacked form with a sensor chip constituting the image sensing device 1140. In an example embodiment, the image sensor 1142 may include a first chip, the control logic 1144, the storage 1150, and the memory 1146 may include a second chip, and the first and second chips may be stacked.

In an example embodiment, the storage 1150 may include an electrically erasable programmable read-only memory (EEPROM), for example. In an example embodiment, the image sensor 1142 may include a pixel array, and the control logic 1144 may include an analog to digital converter and an image signal processor for processing the sensed image.

Referring to FIGS. 15 and 16, in an example embodiment, each of the plurality of camera modules 1100a, 1100b, and 1100c may include an actuator 1130. Accordingly, the plurality of camera modules 1100a, 1100b, and 1100c may include the calibration data 1147 which are the same as each other or different from each other according to an operation of the actuator 1130 included therein.

In an example embodiment, one camera module (e.g., 1100b) among the plurality of camera modules 1100a, 1100b, and 1100c may be a folded lens-type camera module including the prism 1105 and OPFE 1110 described above, and the other camera modules (e.g., 1100a and 1100c) may be vertical-type camera modules that do not include the prism 1105 and the OPFE 1110.

In an example embodiment, one camera module (e.g., 1100c) among the plurality of camera modules 1100a, 1100b, and 1100c may be a depth camera of a vertical shape for extracting depth information by using, e.g., infrared ray (IR). In this case, the application processor 1200 may merge image data provided from the depth camera with image data provided from another camera module (e.g., 1100a or 1100b) and provide a three-dimensional (3D) depth image.

In an example embodiment, at least two camera modules (e.g., 1100a and 1100b) among the plurality of camera modules 1100a, 1100b, and 1100c may have different angles of field of view. In this case, for example, optical lenses of at least two camera modules (e.g., 1100a and 1100b) among the plurality of camera modules 1100a, 1100b, and 1100c may be different from each other.

In an example embodiment, angles of field of view of each of the plurality of camera modules 1100a, 1100b, and 1100c may be different from each other. For example, the camera module 1100a may be an ultrawide camera, the camera module 1100b may be a wide camera, and the camera module 1100c may be a tele camera. In this case, the optical lenses included in each of the plurality of camera modules 1100a, 1100b, and 1100c may also be different from each other.

In an example embodiment, the plurality of camera modules 1100a, 1100b, and 1100c may be physically separated from each other and arranged. Thus, a sensing region of one image sensor 1142 may not be divided or shared by the plurality of camera modules 1100a, 1100b, and 1100c, and an independent image sensor 1142 may be arranged inside each of the plurality of camera modules 1100a, 1100b, and 1100c.

Referring back to FIG. 15, the application processor 1200 may include an image processing device 1210, a memory controller 1220, and an internal memory 1230. The application processor 1200 may implemented separately from the plurality of camera modules 1100a, 1100b, and 1100c. For example, the application processor 1200 and the plurality of camera modules 1100a, 1100b, and 1100c may be implemented as separate semiconductor chips. The image processing device 1210 may include a plurality of sub-image processors 1212a, 1212b, and 1212c, an image generator 1214, and a camera module controller 1216.

The image processing device 1210 may include the plurality of sub-image processors 1212a, 1212b, and 1212c corresponding to the plurality of camera modules 1100a, 1100b, and 1100c, respectively.

Image data generated from each of the camera modules 1100a, 1100b, and 1100c may be provided to the corresponding sub-image processors 1212a, 1212b, and 1212c through image signal lines ISLa, ISLb, and ISLc separated from each other. For example, image data generated by the camera module 1100a may be provided to the sub-image processor 1212a through an image signal line ISLa, image data generated by the camera module 1100b may be provided to the sub-image processor 1212b through an image signal line ISLb, and image data generated by the camera module 1100c may be provided to the sub-image processor 1212c through an image signal line ISLc. Such image data transmission may be performed by using, e.g., a camera serial interface (CSI) based on a mobile industry processor interface (MIPI).

In an example embodiment, one sub-image processor may be arranged to correspond to a plurality of camera modules. For example, the sub-image processor 1212a and the sub-image processor 1212c may be integrated into one sub-image processor without being separated from each other as shown in FIG. 15A, and image data provided from the camera modules 1100a and 1100c may be selected by a selection element (e.g., a multiplexer) or the like and then provided to the integrated sub-image processor. In this case, the sub-image processor 1212b may receive image data from the camera module 1100b without being integrated thereinto.

In an example embodiment, image data generated by the camera module 1100a may be provided to the sub-image processor 1212a through the image signal line ISLa, image data generated by the camera module 1100b may be provided to the sub-image processor 1212b through the image signal line ISLb, and image data generated by the camera module 1100c may be provided to the sub-image processor 1212c through the image signal line ISLc. In addition, image data processed by the sub-image processor 1212b may be directly provided to the image generator 1214, and image data processed by the sub-image processors 1212a and 1212c may be selected by selection elements (e.g., multiplexers) or the like and then provided to the image generator 1214.

Each of the sub-image processors 1212a, 1212b, and 1212c may perform image processing such as bad pixel correction, 3A adjustments (auto-focus correction, auto-white balance, and auto-exposure), noise reduction, sharpening, gamma control, and re-mosaic for the image data provided from the camera modules 1100a, 1100b, and 1100c.

In an example embodiment, re-mosaic signal processing may be performed for each of the camera modules 1100a, 1100b, and 1100c, and then, results of the re-mosaic signal processing may be provided to the sub-image processors 1212a, 1212b, and 1212c.

The image data processed by each of the sub-image processors 1212a, 1212b, and 1212c may be provided to the image generator 1214. The image generator 1214 may generate an output image by using the image data provided from each of the sub-image processors 1212a, 1212b, and 1212c according to image generation information or a mode signal.

The image generator 1214 may generate an output image by merging at least some of the image data generated by the image processors 1212a, 1212b, and 1212c according to the image generation information or the mode signal. The image generator 1214 may generate the output image by selecting any one of the image data generated by the image processors 1212a, 1212b, and 1212c according to the image generation information or the mode signal.

In an example embodiment, the image generation information may include a zoom signal or a zoom factor. The mode signal may be a signal based on, e.g., a mode selected by a user.

When the image generation information is a zoom signal (zoom factor), and when the camera modules 1100a, 1100b, and 1100c have different fields of view (angles of field of view), the image generator 1214 may perform different operations depending on types of the zoom signal. For example, when the zoom signal is a first signal, the image generator 1214 may generate an output image by using image data outputted from the sub-image processors 1212a and 1212b among image data outputted from the sub-image processors 1212a and 1212c. When the zoom signal is a second signal different from the first signal, the image generator 1214 may generate an output image by using image data outputted from the sub-image processors 1212c and 1212b among image data outputted from the sub-image processors 1212a and 1212c. If the zoom signal is a third signal different from the first signal and the second signal, the image generator 1214 does not perform the image data merging and generate the output image by selecting any one of image data outputted from each of the sub-image processors 1212a, 1212b, and 1212c. A method of processing image data may be modified to meet application criteria.

In an example embodiment, the image processing device 1210 may further include a selector (not shown) that selects outputs of the sub-image processors 1212a, 1212b, and 1212c and transmits the selected output to the image generator 1214. In an example embodiment, the selection unit may be implemented as a multiplexer, e.g., a 3×1 multiplexer.

In this case, the selector may perform different operations according to a zoom signal or a zoom factor. For example, when the zoom signal is a fourth signal (e.g., a zoom ratio is a first ratio), the selector may select any one of outputs of the sub-image processors 1212a, 1212b, and 1212c and transmit the selected output to the image generator 1214.

In addition, when the zoom signal is a fifth signal different from the fourth signal (e.g., the zoom ratio is a second ratio), the selector may sequentially transmit p (p is a natural number greater than or equal to 2) outputs among the outputs of the sub-image processors 1212a, 1212b, and 1212c to the image generator 1214. For example, the selector may sequentially transmit the output of the sub-image processor 1212b and the output of the sub-image processor 1212c to the image generator 1214. The selector may sequentially transmit the output of the sub-image processor 1212a and the output of the sub-image processor 1212b to the image generator 1214. The image generator 1214 may generate one output image by merging the p outputs that are sequentially received.

The sub-image processors 1212a, 1212b, and 1212c may perform image processing such as re-mosaic, down scaling to a video/preview resolution size, gamma correction, and high dynamic range (HDR) processing, and then the processed image data is transmitted to the image generator 1214. Accordingly, even when the processed image data is provided to the image generator 1214 through the selector and one signal line, an image merging operation of the image generator 1214 may be performed at a high speed.

In an example embodiment, the image generator 1214 may receive a plurality of pieces of image data having different exposure times from at least one of the plurality of sub-image processors 1212a, 1212b, and 1212c, and perform the high dynamic range (HDR) processing on the plurality of pieces of image data, thereby generating merged image data with an increased dynamic range.

The camera module controller 1216 may provide control signals to the camera modules 1100a, 1100b, and 1100c. The control signals generated by the camera module controller 1216 may be provided to the corresponding camera modules 1100a, 1100b, and 1100c through the control signal lines CSLa, CSLb, and CSLc separated from each other.

Any one of the plurality of camera modules 1100a, 1100b, and 1100c may be designated as a master camera (e.g., 1100b) according to image generation information including a zoom signal, or a mode signal, and the other camera modules (e.g., 1100a and 1100c) may be designated as slave cameras. Such information may be included in the control signals and provided to the corresponding camera modules 1100a, 1100b, and 1100c through the control signal lines CSLa, CSLb, and CSLc separated from each other.

Camera modules operating as a master and slaves may be changed according to a zoom factor or an operation mode signal. For example, when an angle of field of view of the camera module 1100a is wider than an angle of field of view of the camera module 1100b and a zoom factor thereof represents a low zoom ratio, the camera module 1100a may operate as a master, and the camera module 1100b may operate as a slave. In contrast to this, when the zoom factor represents a high zoom ratio, the camera module 1100b may operate as a master and the camera module 1100a may operate as a slave.

In an example embodiment, the control signal provided from the camera module controller 1216 to each of the camera modules 1100a, 1100b, and 1100c may include a sync enable signal. For example, when the camera module 1100b is a master camera and the camera modules 1100a and 1100c are slave cameras, the camera module controller 1216 may transmit the sync enable signal to the camera module 1100b. When receiving the sync enable signal, the camera module 1100b may generate a sync signal based on the provided sync enable signal and transmit the generated sync signal to the camera modules 1100a and 1100c through a sync signal line SSL. The camera module 1100b and the camera modules 1100a and 1100c may be synchronized with the sync signal to transmit image data to the application processor 1200.

In an example embodiment, the control signals provided from the camera module controller 1216 to the plurality of camera modules 1100a, 1100b, and 1100c may include mode information according to a mode signal. The plurality of camera modules 1100a, 1100b, and 1100c may operate in a first operation mode and a second operation mode in relation to a sensing speed, based on the mode information.

The plurality of camera modules 1100a, 1100b, and 1100c may generate image signals at a first speed in a first operation mode (e.g., generate the image signals of a first frame rate), and encode the image signals at a second speed higher than the first speed (e.g., encode image signals of a second frame rate higher than the first frame rate), and transmit the encoded image signals to the application processor 1200. In this case, the second speed may be lower than or equal to 30 times the first speed.

The application processor 1200 may store the received image signal, that is, the encoded image signal, in the memory 1230 included therein or in the external memory 1400 outside the application processor 1200, and then, read the encoded image signal from the memory 1230 or the external memory 1400 and decode the encoded signal, and display image data generated based on the decoded image signal. For example, a corresponding sub-image processor among the plurality of sub-image processors 1212a, 1212b, and 1212c of the image processing device 1210 may perform decoding, and also perform image processing on the decoded image signal.

The plurality of camera modules 1100a, 1100b, and 1100c may each generate an image signal at a third speed lower than the first speed in the second operation mode (e.g., an image signal of a third frame rate lower than the first frame rate) and transmit the image signal to the application processor 1200. The image signal provided to the application processor 1200 may be a signal which is not encoded. The application processor 1200 may perform image processing on the received image signal or may store the image signal in the memory 1230 or the external memory 1400.

The PMIC 1300 may supply power, e.g., a power supply voltage to the plurality of camera modules 1100a, 1100b, and 1100c. For example, the PMIC 1300 may supply first power to the camera module 1100a through a power signal line PSLa, second power to the camera module 1100b through a power signal line PSLb, and third power to the camera module 1100c through a power signal line PSLc, under the control of the application processor 1200.

The PMIC 1300 may generate power corresponding to each of the plurality of camera modules 1100a, 1100b, and 1100c in response to a power control signal PCON from the application processor 1200 and may also adjust a level of the power. The power control signal PCON may include power adjustment signals for each operation mode of the plurality of camera modules 1100a, 1100b, and 1100c. For example, the operation mode may include a low power mode, and in this case, the power control signal PCON may include information on a camera module operating in the low power mode and a level of power to be set. Levels of powers provided to the plurality of camera modules 1100a, 1100b, and 1100c may be the same as each other or different from each other. The levels of power may be dynamically changed.

By way of summation and review, dual conversion gain technology (in which one pixel has two conversion gains) and a pixel array in which pixels share floating diffusion nodes are being studied to increase dynamic range of an image sensor.

As described above, embodiments relate to a pixel array having pixels sharing floating diffusion nodes, and an image sensor including the same. Embodiments may provide a pixel array having a pixel structure in which pixels share floating diffusion nodes so that a dual conversion gain is obtained, to generate an image with improved picture quality, and an image sensor including the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A pixel array for an image sensor, the pixel array comprising:
a first pixel including a floating diffusion node, and including a first selection transistor configured to output a first pixel signal generated using a voltage of the floating diffusion node of the first pixel;
a second pixel including a floating diffusion node, and including a second selection transistor configured to output a second pixel signal generated using a voltage of the floating diffusion node of the second pixel; and
a column line connected to both the first selection transistor and the second selection transistor,
wherein the floating diffusion node of the first pixel and the floating diffusion node of the second pixel are configured to be electrically connected to each other, and the first selection transistor and the second selection transistor are configured to be turned on so that the first pixel signal and the second pixel signal are output to the column line, in a low conversion gain mode.

2. The pixel array as claimed in claim 1, wherein:
the first pixel is arranged in a first row of the pixel array, and
the second pixel is arranged in a second row closest to the first row in the pixel array.

3. The pixel array as claimed in claim 1, wherein:
the first pixel further includes a first photoelectric conversion element configured to generate a first charge based on light incident on the first pixel, and a first transmission transistor configured to transmit the first charge to the floating diffusion node of the first pixel,
the second pixel further includes a second photoelectric conversion element configured to generate a second charge based on light incident on the second pixel, and a second transmission transistor configured to transmit the second charge to the floating diffusion node of the second pixel, and
the first transmission transistor is configured to be turned on in a first horizontal readout period so that the first charge is stored in the floating diffusion node of the first pixel and the floating diffusion node of the second pixel.

4. The pixel array as claimed in claim 1, wherein:
the first pixel further includes a first reset transistor controlled by a reset voltage, and a first gain control transistor serially connected between the first reset transistor and the floating diffusion node of the first pixel,
the second pixel further includes a second reset transistor controlled by the reset voltage, and a second gain control transistor serially connected between the second reset transistor and the floating diffusion node of the second pixel and connected to the first gain control transistor, and
the first gain control transistor and the second gain control transistor are configured to be turned on in the low conversion gain mode.

5. The pixel array as claimed in claim 4, wherein the first gain control transistor and the second gain control transistor are directly connected to each other.

6. The pixel array as claimed in claim 4, wherein the first pixel further includes a connection transistor connected between the first gain control transistor and the second gain control transistor, the connection transistor being configured to be turned on in the low conversion gain mode.

7. The pixel array as claimed in claim 1, wherein each of the first pixel and the second pixel includes:
a plurality of photoelectric conversion elements; and
a plurality of transmission transistors configured to transmit a charge, generated by a corresponding photoelectric conversion element, to a corresponding floating diffusion node.

8. The pixel array as claimed in claim 1, wherein:
the first pixel is configured to sequentially operate in the low conversion gain mode, a high conversion gain mode, and the low conversion gain mode, during a first horizontal readout period in which the first pixel signal is read from the first pixel, and
the floating diffusion node of the first pixel and the floating diffusion node of the second pixel are configured to be electrically isolated from each other, the first selection transistor is configured to be turned on, and the second selection transistor is configured to be turned off, in the high conversion gain mode.

9. The pixel array as claimed in claim 1, further comprising a third pixel including a floating diffusion node, and a third selection transistor configured to output a third pixel signal generated using a voltage of the floating diffusion node of the third pixel,
wherein the floating diffusion nodes of the first, second, and third pixels are configured to be electrically connected to one another, and the first, second, and third selection transistors are configured to be turned on so that the first, second, and third pixel signals are output to the column line, in the low conversion gain mode.

10. The pixel array as claimed in claim 1, wherein color filters of a same color are arranged on the first pixel and the second pixel.

11. A pixel array for an image sensor, the pixel array comprising:
a plurality of column lines; and
a plurality of pixels arranged in a matrix and including at least a first pixel and a second pixel that are connected to a first column line of the plurality of column lines, each of the first and second pixels including:
a first floating diffusion node;
a second floating diffusion node;
a photoelectric conversion element configured to receive an optical signal and generate a corresponding charge;
a transmission transistor configured to transmit the charge to the first floating diffusion node;
a gain control transistor connected between the first floating diffusion node and the second floating diffusion node;
a driving transistor configured to generate a pixel signal in accordance with a voltage of the first floating diffusion node; and
a selection transistor configured to output the pixel signal to the first column line,
wherein the first and second floating diffusion nodes of the first and second pixels are configured to be electrically connected to one another, and the selection transistors of the first and second pixels are configured to be turned on, in a low conversion gain mode.

12. The pixel array as claimed in claim 11, wherein the first pixel and the second pixel connected to the first column line are arranged in different rows of the matrix.

13. The pixel array as claimed in claim 11, wherein the first pixel and the second pixel connected to the first column line are arranged in the same row and different columns of the matrix.

14. The pixel array as claimed in claim 11, further comprising a third pixel and a fourth pixel, each connected to the first column line, and each including a first floating diffusion node, a second floating diffusion node, and a selection transistor,
wherein the first and second floating diffusion nodes of the third and fourth pixels are configured to be electrically connected to one another and to the first and second floating diffusion nodes of the first and second pixels, and the selection transistors of the third and fourth pixels are configured to be turned on, in the low conversion gain mode.

15. The pixel array as claimed in claim 14, wherein the first pixel, the second pixel, the third pixel, and the fourth pixel are arranged in a 2×2 matrix.

16. An image sensor, comprising:
a pixel array including a plurality of pixels arranged in a matrix, in which a first pixel and a second pixel connected to a first column line are connected to each other;
a row driver configured to drive the first pixel and the second pixel so that a floating diffusion node of the first pixel and a floating diffusion node of the second pixel are connected to each other in a low conversion gain mode, and the first pixel outputs a first pixel signal and the second pixel outputs a second pixel signal; and
an analog-to-digital converter configured to analog-to-digital convert the first and second pixel signals output from the first column line.

17. The image sensor as claimed in claim 16, wherein the first pixel and the second pixel are adjacent to each other in a column direction of the pixel array.

18. The image sensor as claimed in claim 16, wherein each of the first pixel and the second pixel includes:
a first floating diffusion node;
a second floating diffusion node;
a photoelectric conversion element configured to receive an optical signal and generate a corresponding charge;
a transmission transistor configured to transmit the charge to the first floating diffusion node;
a gain control transistor connected between the first floating diffusion node and the second floating diffusion node;
a driving transistor configured to generate a corresponding one of the first and second pixel signals in accordance with a voltage of the first floating diffusion node; and
a selection transistor connected to the first column line and configured to output the corresponding one of the first and second pixel signals to the first column line.

19. The image sensor as claimed in claim 18, wherein the first pixel further includes a connection transistor connected between the second floating diffusion node of the first pixel and the second floating diffusion node of the second pixel.

20. The image sensor as claimed in claim 16, wherein color filters of a same color are arranged on the first pixel and the second pixel.
